(19) United States
(12) Patent Application Publication
(10) Pub. No.: US 2026/0293689 A1
(43) Pub. Date: Sep. 24, 2026

(54) ELECTRONIC DEVICES AND METHODS OF MANUFACTURING ELECTRONIC DEVICES

(71) Applicant: Amkor Technology Singapore Holding Pte. Ltd., Valley Point (SG)

(72) Inventors: In Su MOK, Incheon (KR); Ji Hye YOON, Gyeonggi-do (KR); Soo Hyun KIM, Incheon (KR); Su Hwan BAE, Incheon (KR)

(73) Assignee: Amkor Technology Singapore Holding Pte. Ltd., Valley Point (SG)

(21) Appl. No.: 19/447,189

(22) Filed: Jan. 13, 2026

Related U.S. Application Data
(60) Provisional application No. 63/774,643, filed on Mar. 19, 2025.

(51) Int. Cl. H10W 42/20; H10W 70/05; H10W 72/00; H10W 74/01; H10W 74/10; H10W 90/00

(52) U.S. Cl. CPC H10W 42/276; H10W 70/093; H10W 72/823; H10W 74/01; H10W 74/111; H10W 90/724; H10W 90/7295

(57) ABSTRACT

In one example, a method of manufacturing an electronic device includes providing a first carrier comprising an inner side. The method includes coupling interconnect structures to the inner side of the first carrier. The method includes providing a first electronic component comprising a first electronic component first side and a first electronic component second side and coupling the first electronic component to the inner side of the first carrier. The method includes providing an encapsulant covering the interconnect structures and the first electronic component and exposing upper ends of the interconnect structures from an outer side of the encapsulant. The method includes in either order providing a package substrate coupled to the first electronic component and the interconnect structures; and providing a shield over the encapsulant and coupled to the interconnect structures. The method includes singulating the package substrate, the encapsulant, and the shield to provide the electronic device.

### CROSS-REFERENCES TO RELATED APPLICATIONS

This application claims priority from U.S. Provisional Application No. 63/774,643 filed on Mar. 19, 2025, which is hereby incorporated by reference and priority thereto is claimed.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, and 2G show cross-sectional views of an example method for manufacturing an example electronic device.

FIG. 3 shows a cross-sectional view of an example electronic device.

FIGS. 4A, 4B, 4C, 4D, 4E, 4F, and 4G show cross-sectional views of an example method for manufacturing an example electronic device.

FIG. 5 shows a cross-sectional view of an example electronic device.

FIG. 6 shows a plan view of an example electronic device.

FIG. 7 shows a cross-sectional view of an example electronic device.

FIGS. 8A, 8B, 8C, 8D, and 8E show cross-sectional views of an example method for manufacturing an example electronic device.

FIG. 9 shows a cross-sectional view of an example electronic device.

FIG. 10 shows a cross-sectional view of an example electronic device.

FIGS. 11A, 11B, 11C, 11D, 11E, 11F, and 11G show cross-sectional views of an example method for manufacturing an example electronic device.

FIG. 12 shows a cross-sectional view of an example electronic device.

FIGS. 13A, 13B, 13C, 13D, 13E, 13F, 13G, and 13H show cross-sectional views of an example method for manufacturing an example electronic device.

FIG. 14 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “for example” are non-limiting.

The figures illustrate the general manner of construction, and descriptions and details of well-known features and techniques can be omitted to avoid unnecessarily obscuring the present disclosure. In addition, elements in the drawing figures are not necessarily drawn to scale. For example, the dimensions of some of the elements in the figures can be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. can be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. As used herein, the term “coupled” can refer to a mechanical coupling or an electrical coupling.

### DESCRIPTION

The present description includes, among other features, structures and associated methods that relate to electronic devices including, for example, semiconductor devices, configured with electromagnetic interference (EMI) shield structures. In some examples, wafer-level assembly processes are used to simplify connectivity to shield structures and to avoid the implications of package edge exclusion requirements of previous package structures, such as keep-out zones. In some examples, conductive interconnects, electronic components, an encapsulant, and a top shield are provided using a carrier prior to providing a substrate coupled to the electronic components and the conductive interconnects. External interconnects can be provided after providing the substrate. In other examples, the substrate is provided on a carrier, the conductive interconnects, electronic components, encapsulant, and top shield are then provided. After removing the carrier, external interconnects are then provided coupled to the substrate. Among other things, the structures and methods provide an electronic package with improved performance and reliability by reducing susceptibility to EMI and by improving thermal performance.

In an example, a method of manufacturing an electronic device includes providing a first carrier comprising an inner side. The method includes coupling interconnect structures to the inner side of the first carrier. The method includes providing a first electronic component comprising a first electronic component first side and a first electronic component second side and coupling the first electronic component to the inner side of the first carrier. The method includes providing an encapsulant covering the interconnect structures and the first electronic component and exposing upper ends of the interconnect structures from an outer side of the encapsulant. The method includes in either order providing a package substrate coupled to the first electronic component and the interconnect structures; and providing a shield over the encapsulant and coupled to the interconnect structures. The method includes singulating the package substrate, the encapsulant, and the shield to provide the electronic device. In some examples, providing the shield occurs before providing the package substrate. In some examples, providing the package substrate occurs before providing the shield.

In an example, a method of manufacturing an electronic device includes providing a first carrier comprising an inner side. The method includes coupling interconnect structures and a first electronic component to the first carrier, wherein an active side of the first electronic component and proximate ends of the interconnect structures are adjacent to the inner side of the first carrier. The method includes providing encapsulant covering the interconnect structures and the first electronic component and removing a top portion of the encapsulant to expose distal ends of the interconnect structures. The method includes providing a shield over a top side of the encapsulant, wherein the shield is coupled to the interconnect structures. The method includes removing the first carrier and coupling a second carrier to the shield. The method includes providing a substrate coupled to the proximate ends of the interconnect structures and the active side of the first electronic component. The method includes singulating the substrate, the encapsulant, and the shield to provide the electronic device.

In an example, an electronic device includes a redistribution layer substrate (RDL substrate) comprising an inner side and an outer side and electronic components comprising component connectors are coupled to the inner side of the RDL substrate. Interconnect structures are coupled to the inner side of the RDL substrate and adjacent to the electronic components. An encapsulant covers the electronic components and the interconnect structures and distal ends of the interconnect structures are exposed from an upper side of the encapsulant. A top shield is on the upper side of the encapsulant and coupled to the interconnect structures. The encapsulant comprises lateral sides, and the lateral sides are devoid of the top shield. External interconnects coupled to the outer side of the RDL substrate, wherein the top shield and the interconnect structures provide a shielding structure for the electronic device.

Other examples are included in the present disclosure. Such examples can be found in the figures, in the claims, or in the description of the present disclosure.

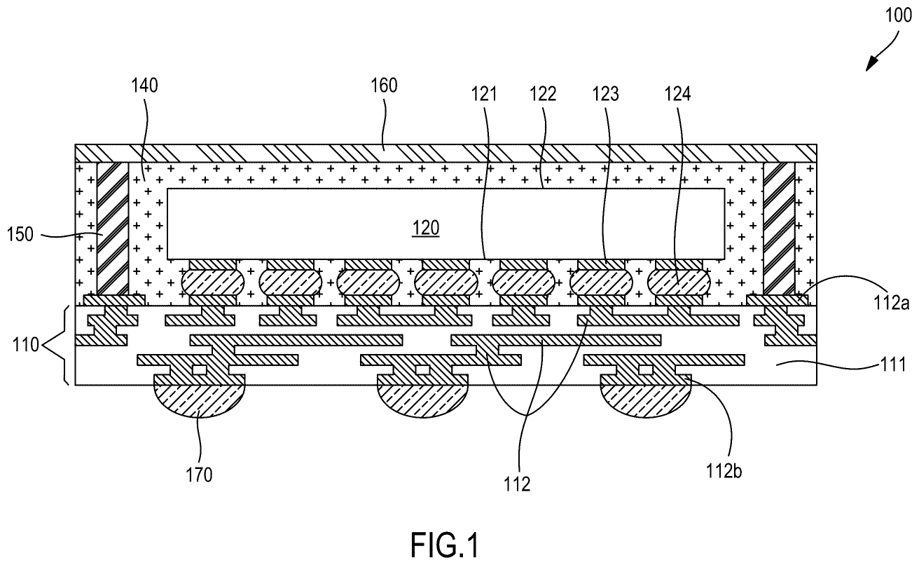

FIG. 1 shows a cross-sectional view of an example electronic device 100. In the example shown in FIG. 1, electronic device 100 can comprise substrate 110, electronic component 120, encapsulant 140, interconnect structures 150, shield 160, and external interconnects 170.

Substrate 110 can comprise dielectric structure 111 and conductive structure 112. Conductive structure 112 can comprise substrate inward terminals 112a and substrate outward terminals 112b. Electronic component 120 can comprise electronic component first side 121, electronic component second side 122, and electronic component contact pads 123. In some examples, connectors 124 are used to couple electronic component contact pads 123 of electronic component 120 to conductive structure 112. In some examples, connectors 124 can be provided as part of electronic component 120.

Substrate 110, encapsulant 140, interconnect structures 150, shield 160, and external interconnects 170 can be referred to as an electronic package or a semiconductor package, and the package can provide protection for electronic component 120 from external elements or external exposure. The semiconductor package can provide electrical coupling between electronic component 120 and external electronic components.

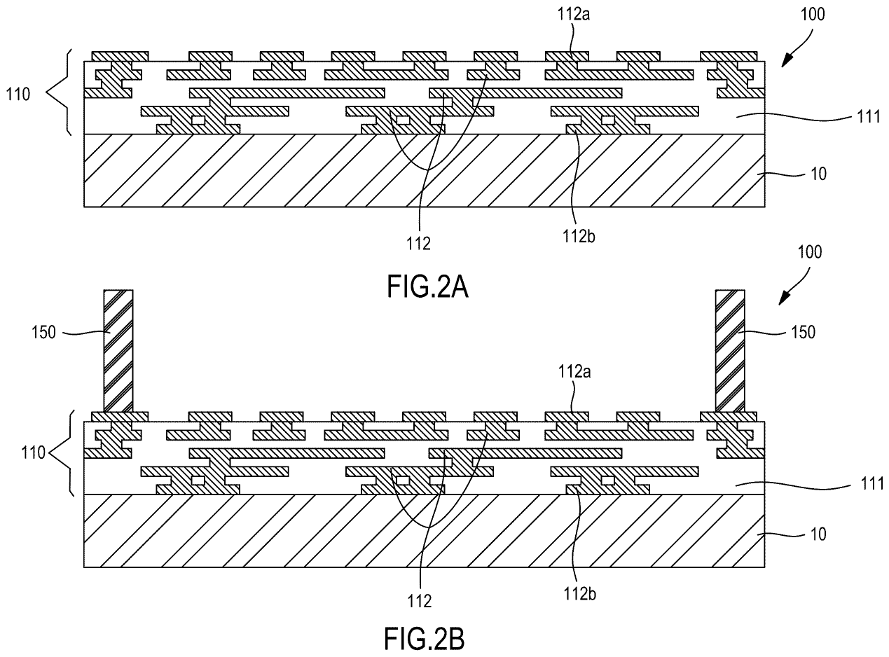

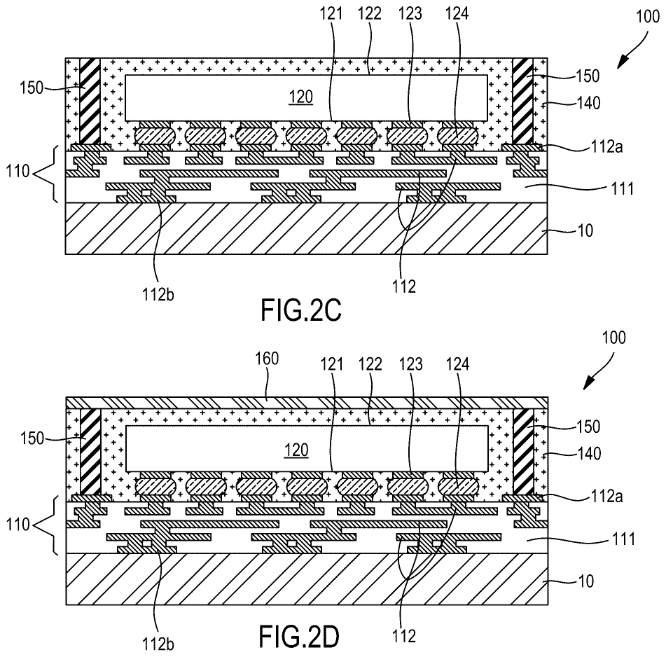

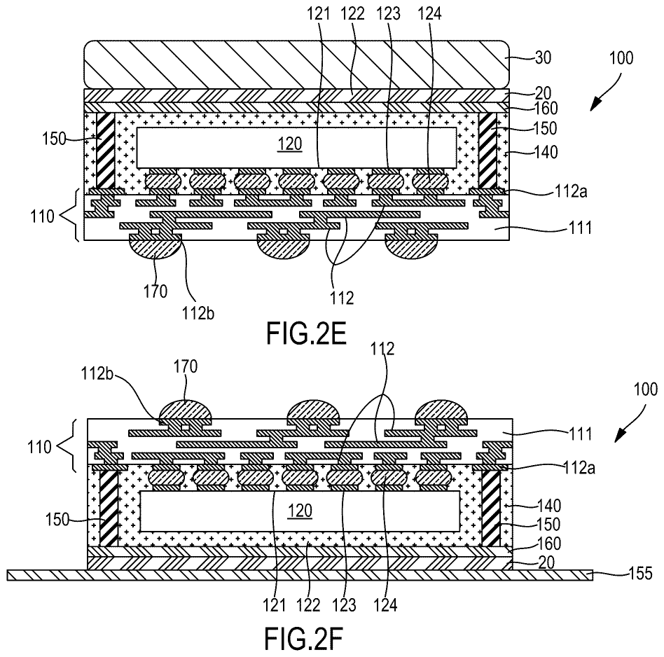

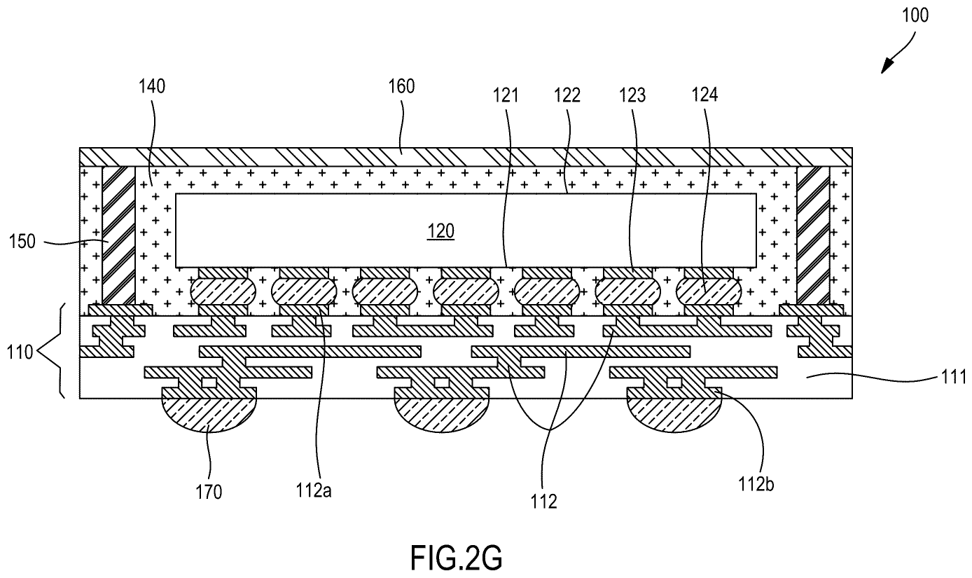

FIGS. 2A, 2B, 2C, 2D, 2E, 2F, and 2G show cross-sectional views of an example method for manufacturing an example electronic device, such as electronic device 100. FIG. 2A shows a cross-sectional view of electronic device 100 at an early stage of manufacture. In the present specification, electronic device 100 can be referred to as an electronic package, semiconductor device, semiconductor package, device, assembly, structure, or package.

In the example shown in FIG. 2A, carrier 10 can be provided. Carrier 10 can comprise any of a variety of features. Carrier 10 can comprise, for example, a carrier for a single electronic device (or package), or can comprise, for example, a wafer or a panel where any number of electronic devices (or packages) can be formed. Carrier 10 can also comprise, for example, a glass wafer or panel, a metal wafer or panel, a ceramic wafer or panel, a plastic wafer or panel, or other materials or structures as known to one of ordinary skill in the art.

In some examples, a temporary bonding layer can be provided on the surface of carrier 10. In some examples, the temporary bonding layer can comprise a layer of adhesive paste, a layer of liquid adhesive, a preformed double-sided adhesive tape or sheet (for example, die-attach tape), a printing adhesive, or similar materials as known to one of ordinary skill in the art. The temporary bonding layer can partially or completely cover, for example, the top side of carrier 10. The temporary bonding layer can be provided by, for example, applying the preformed sheet or film of the temporary bonding layer on carrier 10, printing the temporary bonding layer on carrier 10, spin-coating the temporary bonding layer on carrier 10, dipping carrier 10 into an adhesive, or spraying the temporary bonding layer on carrier 10. In some examples, the temporary bonding layer can be provided on the surface of carrier 10 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape.

In some examples, the temporary bonding layer can be referred to as a temporary adhesive film, a temporary adhesive tape, or a temporary adhesive coating or an adhesive layer. For example, the temporary bonding layer can be a heat-release tape (film) or a light-release tape (film), the adhesive strength can be weakened or removed by heat or light. In some examples, the temporary bonding layer can have an adhesive strength weakened or removed due to external physical or chemical forces. The temporary bonding layer can allow carrier 10 to be separated from substrate 110 before external interconnects 170 (FIG. 2E) are provided.

Carrier 10 can comprise a planar plate, wafer, or panel. In some examples, carrier 10 can comprise or be referred to as a plate, board, wafer, panel, or strip. For example, carrier 10 can be made of steel, stainless steel, aluminum, copper, ceramic, glass, or a wafer. In some examples, the thickness of carrier 10 can range from approximately 300 micrometers (microns or microns) to approximately 2000 microns, and the width of carrier 10 can range from approximately 100 millimeters (mm) to approximately 650 mm. Carrier 10 serves to handle multiple components as one in the process of providing substrate 110, electronic component 120, encapsulant 140, and interconnect structures 150.

In the example shown in FIG. 2A, substrate 110 can be provided on the upper side of carrier 10. In some examples, a signal distribution structure can be provided on the upper side of carrier 10. For example, the signal distribution structure can be provided by forming and patterning one or more dielectric structural layers and one or more conductive structural layers. The signal distribution structure can also comprise or be referred to as a redistribution layer, a redistribution layer stack, a redistribution structure, or an interposer. In some examples, dielectric structure 111 or conductive structure 112 can comprise any number of layers.

In some examples, conductive structure 112 can be provided through any one or more of a variety of processes, for example, electroplating, electroless plating, chemical vapor deposition (CVD), metal organic chemical vapor deposition (MOCVD), sputtering or physical vapor deposition (PVD), atomic layer deposition (ALD), plasma vapor deposition, printing, screen printing, lithography, or other processes as known to one of ordinary skill in the art. In the present specification, conductive structure 112 can be one or more conductive layers. In some examples, conductive structure 112 defines signal distribution elements and can comprise or be referred to as traces, vias, pads, conductive paths, or UBMs.

In some examples, conductive structure 112 can comprise substrate inward terminals 112a and substrate outward terminals 112b. In some examples, conductive structure 112 can comprise or be referred to as a conductive layer, a trace, a pad, a via, a redistribution layer (RDL), a wiring pattern, a circuit pattern, a signal distribution layer, under bump metallization (UBM), a land layer, or a bond pad layer. In some examples, conductive structure 112 can comprise a conductor, such as copper, gold, silver, nickel, aluminum, iron, titanium, chromium, tungsten, palladium, combinations thereof, or other conductive materials as known to one of ordinary skill tine art. In some examples, conductive structure 112 can comprise, for example, a combination of at least two of, aluminum, iron, titanium, chromium, tungsten, palladium. In some examples, conductive structure 112 can comprise, for example, an alloy of at least two of, aluminum, iron, titanium, chromium, tungsten, palladium.

In some examples, substrate outward terminals 112b can be provided on the upper side or inner side of carrier 10. Substrate outward terminals 112b can be provided to have multiple patterns on the surface of carrier 10. In some examples, substrate outward terminals 112b can comprise or be referred to as pads, or lands. In some examples, substrate outward terminals 112b can comprise copper, gold, silver, or nickel. In some examples, substrate outward terminals 112b can be provided by plating. For example, substrate outward terminals 112b can be provided with a metal seed layer to cover the upper side of carrier 10, a mask pattern can be provided to cover the upper side of the seed layer, which can be a thin conductive film deposited onto carrier 10 to enable uniform and reliable plating of materials. A plating can then be provided to have a pattern using the seed layer as a foundation. For example, a photoresist can be used as a mask pattern. The mask pattern can be removed after substrate outward terminals 112b are formed. In some examples, the thicknesses of substrate outward terminals 112b can range from approximately 1 micron to approximately 2000 microns.

Dielectric structure 111 can be provided on substrate outward terminals 112b and carrier 10. In some examples, dielectric structure 111 can be interleaved with conductive structure 112. After dielectric structure 111 is provided to cover substrate outward terminals 112b and carrier 10, openings can be provided to expose substrate outward terminals 112b. For example, the openings can be provided by providing a mask pattern on the upper side of dielectric structure 111 and then removing exposed dielectric structure 111 using for example, an etching process. In some examples, the openings can be referred to as or can comprise apertures or holes. In some examples, dielectric structure 111 can comprise or be referred to as a dielectric layer, a coreless layer, or a filler-free layer. For example, dielectric structure 111 can comprise an electrically insulating material such as polyimide (PI), benzocyclobutene (BCB), polybenzoxazole (PBO), resin or an Ajinomoto buildup film (ABF). In some examples, dielectric structure 111 can comprise resin, mold, ceramic, glass, or Si. In some examples, dielectric structure 111 can be provided by spin coating, spray coating, dip coating, or rod coating. In some examples, dielectric structure 111 can be provided through any one or more of a variety of processes (for example, spin coating, spray coating, printing, sintering, thermal oxidation, physical vapor deposition (PVD), chemical vapor deposition (CVD), metal organic chemical vapor deposition (MOCVD), atomic Layer deposition (ALD), low pressure chemical vapor deposition (LPCVD), plasma enhanced chemical vapor deposition (PECVD), plasma vapor deposition (PVD) or sheet deposition, or vaporization. In some examples, the thickness of dielectric structure 111 can range from approximately 10 microns to approximately 2000 microns.

Substrate inward terminals 112a can be provided at the upper side of dielectric structure 111. Substrate inward terminals 112a can be provided to have multiple patterns. In some examples, substrate inward terminals 112a can comprise or be referred to as pads, lands, under bump metallization (UBM), or studs. In some examples, substrate inward terminals 112a can comprise copper, gold, silver or nickel. Substrate inward terminals 112a can have corresponding elements, features, materials, or manufacturing methods similar to those of substrate outward terminals 112b described above. In some examples, substrate inward terminals 112a can be positioned on top of dielectric structure 111. In other examples, substrate inward terminals 112a can be partially embedded within dielectric structure 111. Substrate outward terminals 112b and substrate inward terminals 112a can be parts of conductive structure 112. In this regard, conductive structure 112 can electronically couple substrate inward terminals 112a to substrate outward terminals 112b.

Dielectric structure 111 and conductive structure 112 can each comprise any number of layers. One or more layers or elements of conductive structure 112 can be interleaved with dielectric structure 111. In some examples, the overall thickness of substrate 110 can range from approximately 10 microns to approximately 2000 microns.

In some examples, substrate 110 can be a redistribution layer (“RDL”) substrate, also referred to as a build-up substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure, as described below with regard to pre-formed substrates. Other substrates in this disclosure can also comprise an RDL substrate.

In some examples, substrate 110 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thick non-photo-definable layers that can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4. In some examples, the core structure can be glass. The dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can rereferred to as a printed circuit board (PCB) or a laminate substrate. Such pre-formed substrate can be formed through a semi-additive or modified-semi-additive process. Other substrates in this disclosure can also comprise a pre-formed substrate.

FIG. 2B shows a cross-sectional view of electronic device 100 at a later stage of manufacture. In the example shown in FIG. 2B, a plurality of interconnect structures 150 can be coupled (or provided, attached, or formed) inside substrate 110. In some examples, two or more interconnect structures 150 can be provided on the signal distribution structure. In some examples, interconnect structures 150 can be at least partially formed on for example, various portions of conductive structure 112. In some examples, interconnect structures 150 can be provided to extend vertically from the signal distribution structure (for example, from substrate inward terminals 112a, pads or lands, or traces).

In some examples, interconnect structures 150 can include any of a variety of features. For example, interconnect structures 150 can be cylindrical, elliptical, cylindrical, or square. Interconnect structures 150 can have, for example, a flat top end, a concave top end, or a convex top end. Interconnect structures 150 can include, for example, any of the materials with respect to conductive structure 112. In an example implementation, interconnect structures 150 can comprise copper (for example, pure copper or copper having some impurities) or a copper alloy. In some examples, interconnect structures 150 can be made of gold, silver, palladium, or nickel. In some examples, interconnect structures 150 can comprise or be referred to as pillars, posts, wires, through mold vias (TMVs), ball-shaped structures (Cu core solder balls (CCBs)), solder balls (S/B)), or Cu cube column (CCCs).

In some examples, interconnect structures 150 can be provided through any of a variety of processes (for example, electroplating, electroless plating, CVD, MOCVD, sputtering or PVD, ALD, plasma vapor deposition, printing, screen printing, lithography, or other processes as known to one of ordinary skill in the art. In some examples, by attaching preformed wires (for example, die bonding wires), interconnect structures 150 can be provided by filling vias or trenches in a temporary or permanent mask (for example, a photoresist mask or a mold material mask). In some examples, after providing interconnect structures 150, the temporary mask, if used, can be peeled off or removed using, for example, a chemical stripping or ashing process. In some examples, the heights of interconnect structures 150 can range from approximately 3 microns to approximately 500 microns. Interconnect structures 150 can be provided to be spaced apart from each other in the row or column direction. In some examples, a plurality of interconnect structures 150 can be provided. For example, interconnect structures 150 can include any of a variety of patterns to form shielding regions of any or varying shape, size, and number. Interconnect structures 150 can comprise or be referred to as conductive pillars or pillar structures.

FIG. 2C shows a cross-sectional view of electronic device 100 at a later stage of manufacture. In the example shown in FIG. 2C, electronic component 120 can be coupled (or attached or formed) on the uppermost side or top side of substrate 110. In some examples, two or more interconnect structures 150 can be coupled to a first portion of conductive structure 112, or one or more electronic components 120 can be coupled to a second portion of conductive structure 112 between two or more interconnect structures 150.

In some examples, after providing interconnect structures 150, at least one electronic component 120 can be provided adjacent to the uppermost side (or top side) of substrate 110. In some examples, interconnect structures 150 can be in contact with and electrically connected to substrate inward terminals 112a. Interconnect structures 150 can be laterally spaced apart on a plane from electronic component 120. In some examples, the heights of interconnect structures 150 can be greater than the thickness of electronic component 120 as illustrated, for example, in FIG. 2C. In some examples, interconnect structures 150 can be located on both sides of electronic component 120. In some examples, interconnect structures 150 can be provided to be somewhat spaced apart from electronic component 120 along the perimeter of electronic component 120. In some examples, interconnect structures 150 can completely surround electronic component 120.

In some examples, electronic component 120 can comprise electronic component first side 121, electronic component second side 122, contact pads 123, and connectors 124. Electronic component 120 can be in contact with and electrically connected to substrate inward terminals 112a of substrate 110. In some examples, electronic component first side 121 can comprise or be referred to as an active side of electronic component 120. In some examples, electronic component 120 can be oriented so that the active side faces substrate 110 and the inactive side faces away from substrate 110.

In some examples, electronic component 120 can comprise or be referred to as a die, chip, package, or passive device. In some examples, electronic component 120 can comprise or be referred to as a digital signal processor (DSP), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub-6 GHz RF module, an Integrated passive device (IPD), or other components as known to one of ordinary skill in the art.

In some examples, electronic component 120 can be provided with electronic component contact pads 123 and connectors 124 on electronic component first side 121. Electronic component contact pads 123 can be positioned between electronic component 120 and connectors 124. In some examples, electronic component first side 121, for example, electronic component contact pads 123 on the active side, can be electrically connected to the circuit of electronic component 120. Electronic component contact pads 123 can be in contact with electronic component first side 121 and the upper side of connectors 124. Electronic component contact pads 123 can each comprise or be referred to as a bond pad exposed by a dielectric, such as SiN/SiO₂ or an RDL pad exposed by a dielectric material. Electronic component contact pads 123 are configured to reduce the likelihood of separation between electronic component 120 and connectors 124 due to physical and chemical shock. In some examples, electronic component contact pads 123 can be attached (or connected) to portions (for example, pads or lands) where substrate inward terminals 112a of corresponding conductive structure 112 are exposed. This attachment or connection can be performed by, for example, connectors 124.

Connectors 124 can be provided on or adjacent to electronic component first side 121 of electronic component 120 and can be spaced apart from each other in row or column directions. Connectors 124 are configured to couple conductive structure 112 and the electronic component 120 together. Connectors 124 can comprise or be referred to as bumps, pads, or pillars. Connectors 124 can comprise or be referred to as SnPb bumps, lead-free bumps, CuP, stud bumps, or posts. Connectors 124 can be input/output terminals of electronic component 120. In some examples, connectors 124 can be provided on electronic component 120 by electrolytic plating, electroless plating, sputtering, PVD, CVD, MOCVD, ALD, LPCVD, or PECVD. For example, after providing photo resist patterns that expose electronic component contact pads 123 of electronic component 120, connectors 124 can be provided to be in contact with exposed electronic component contact pads 123. In some examples, the thicknesses of connectors 124 can range from approximately 1 micron to approximately 100 microns, and the width and pitch of connectors 124 can range from approximately 10 microns to approximately 300 microns.

In some examples, electronic component 120 can be attached to the uppermost side or inner side of substrate 110 through any of a variety of processes including mass reflow, thermocompression bonding, direct metal-to-metal bonding, laser soldering, conductive epoxy bonding, conductive film bonding, or other processes as known to one of ordinary skill in the art. In some examples, substrate 110 and electronic component contact pads 123 of electronic component 120 can be electrically connected through connectors 124. In some examples, electronic component 120 can be located at the center of substrate 110 but can also be laterally offset from the center of substrate 110. In some examples, multiple or plurality of electronic components 120 can be attached to substrate 110 to be included within the similar packaged electronic device.

In some examples, pick-and-place equipment can be used to pick up electronic component 120 to place electronic component 120 onto substrate 110. Connectors 124 of electronic component 120 can be aligned to and located over substrate inward terminals 112a of substrate 110. Subsequently, connectors 124 of electronic component 120 can be in contact with and bonded to substrate inward terminals 112a through a reflow or thermocompression bonding process. In some examples, electronic component 120 can be electrically connected to substrate 110 through conductive structure 112.

Although electronic component 120 is shown in a face-down or flip-chip configuration with electronic component contact pads 123 located over or on electronic component first side 121, electronic component 120 can be in a face-up or wire bonded configuration with electronic component pads 123 on the upper side. For example, electronic component second side 122 of electronic component 120 can comprise or be referred to as an active side, and electronic component first side 121 can comprise or be referred to as an inactive side. The inactive side of electronic component 120 can be bonded to the upper side or inner side of substrate 110. Electronic component 120 can have a component terminal located on electronic component second side 122 and coupled with the active side. In this configuration, electronic component 120 can comprise or be referred to as a face-up or wire-bonded component. The component terminal of electronic component 120 can be electrically connected to substrate inward terminals 112a of substrate 110 through connectors 124. In this configuration, connectors 124 can comprise or be referred to as conductive wires. For example, the conductive wires can be conductive wires such as gold wires, copper wires, or aluminum wires, and can bond the component terminals of electronic component 120 to substrate inward terminals 112a of substrate 110 using, for example wire bonding equipment.

In some examples, the overall thickness of electronic component 120 can range from approximately 50 microns to approximately 780 microns, and the area of electronic component 120 can range from approximately 0.3 mm×0.3 mm to approximately 70 mm×70 mm.

In some examples, interconnect structures 150 and electronic component 120 can be arranged in any of a variety of ways. For example, electronic component 120 can be laterally surrounded by multiple interconnect structures 150. In some examples, when electronic component 120 is coupled to substrate 110 with electronic component second side 122 facing away from the inner side of substrate 110, electronic component second side 122 can be located on a horizontal plane that is lower than a horizontal plane where the distal ends of interconnect structures 150 are located. In other examples, electronic component second side 122 and the distal ends of interconnect structures 150 can be substantially coplanar. In some examples, the uppermost sides of electronic components 120, interconnect structures 150, or encapsulant 140 (described below) can be planarized surfaces.

In some examples, additional electronic components can be optionally provided coupled to either side of substrate 110. Additional electronic components can comprise, for example, passive components, antenna patches, intelligent power devices (IPDs), or other components as known to one of ordinary skill in the art. In some examples, the additional electronic components can be interconnected by wire bonding (WB) or by flip-chip attachment.

In some examples, conductive structure 112 can comprise one or more antenna patterns. Substrate 110 can be provided with substrate outward terminals 112b including an antenna pattern, dielectric structure 111 can be provided, and substrate inward terminals 112a can then be provided. In some examples, electronic component 120 can be electrically connected to the antenna pattern through conductive structure 112 of substrate 110. In other examples, the antenna pattern can be embedded within substrate 110. In some examples, the antenna pattern can comprise a dipole antenna, a monopole antenna, a patch antenna, a loop antenna, a beam antenna, a doublet antenna, a folded antenna, a rhombic antenna, a half-wave antenna, or other antenna patterns as known to one of ordinary skill in the art. In some examples the antenna pattern can comprise copper, gold, or silver. In some examples, the antenna pattern can be provided by RDL, thereby providing accurate antenna size due to fine size adjustment.

In some examples, one or more passive components can be provided embedded within substrate 110. In other examples, the passive component can be provided on the upper or lower side of substrate 110. In some examples, the passive component can comprise passive component interconnects provided on the lower side. Passive component interconnects can be provided on the lower side of the passive component to be spaced apart from each other in a row or column direction. The passive component interconnects of the passive component can be in contact with and electrically connected to substrate inward terminals 112a or substrate outward terminals 112b of substrate 110. In some examples, pick-and-place equipment can pick up the passive component and place the passive component in a desired location of substrate 110. Subsequently, the passive component interconnects of the passive component can be in contact with and be bonded to substrate inward terminals 112a or substrate outward terminals 112b through a reflow or thermocompression bonding process.

In some examples, the passive component can comprise passive component interconnects provided on the upper side. The lower side of the passive component can be attached to the upper side of substrate 110 through an adhesive. The lower side of the passive component can be attached to dielectric structure 111. In some examples, the adhesive can comprise or be referred to as a polymer or a dielectric. In some examples, pick-and-place equipment can pick up the passive component and place the passive location in a desired location of substrate 110. The passive component can be placed on the upper side of dielectric structure 111 of substrate 110 and be attached using an adhesive. In some examples, the passive component can comprise or be referred to as a passive component or a decoupling capacitor. In some examples, the overall thickness of the passive component can be smaller than the height of interconnect structures 150. In some examples, the passive component can be spaced apart from interconnect structures 150 on a plane.

In the example shown in FIG. 2C, encapsulant 140 can be provided to cover the inner side of substrate 110, electronic component 120, and interconnect structures 150. In some examples, encapsulant 140 can comprise or be referred to as a body, a package body, or a molding. In some examples, encapsulant 140 can be provided through one or more of compression molding, transfer molding, liquid encapsulant molding, liquid body molding, vacuum lamination, paste printing, or film assisted molding. In other examples, encapsulant 140 can be provided through one or more of spin coating, spray coating, printing, sintering, thermal oxidation, PVD, CVD, MOCVD, ALD, LPCVD, PECVD, sheet deposition, or vaporization.

Encapsulant 140 can comprise one or more of a variety of encapsulating materials. In some examples, encapsulant 140 can comprise any material selected from various encapsulating or molding materials (for example, resins, polymers, polymer composites, polymers with fillers, epoxy resins, epoxy resins with fillers, epoxy acrylates with fillers, silicone resins, or combinations of resins, polymers, polymer composites, polymers with fillers, epoxy resins, epoxy resins with fillers, epoxy acrylates with fillers, silicone resins). In some examples, encapsulant 140 can comprise an epoxy molding compound (EMC), resin, filler-reinforced polymer, a B-stage pressed film, or gel. In some examples, encapsulant 140 can comprise any dielectric material selected from various dielectric materials, such as inorganic dielectric materials (for example, Si₃N₄, SiO₂, SiON, SiN, oxide, nitride, or combinations of SisN₄, SiO₂, SION, SiN, oxide, nitride) or organic dielectric materials (for example polymers, polyimide (PI), benzocyclobutene (BCB), polybenzoxazole (PBO), bismaleimide triazine (BT), molding materials, phenol resin, epoxy, silicone, acrylate polymer, or combinations of polymers, polyimide (PI), benzocyclobutene (BCB), polybenzoxazole (PBO), bismaleimide triazine (BT), molding materials, phenol resin, epoxy, silicone, acrylate polymer).

In some examples, the top portion or a portion of the outer side of encapsulant 140 can be removed to expose the upper sides or distal ends of interconnect structures 150. In some examples, the top portion of encapsulant 140 can be removed by grinding, polishing, etching, or combinations thereof. In some examples, when the top portion of encapsulant 140 is removed, the top portions of interconnect structures 150 can also be removed to define the distal ends of interconnect structures 150. In the present example, the upper side of encapsulant 140 is coplanar with the distal ends of interconnect structures 150. In this way, the thickness of encapsulant 140 and the heights of interconnect structures 150 can be similar. Encapsulant 140 can be in contact with the inner side of substrate 110 and the sidewalls of interconnect structures 150. In some examples, the thickness of encapsulant 140 can range from approximately 3 microns to approximately 500 microns

In some examples, encapsulant 140 can be provided to cover the inner side or upper side of substrate 110, portions of substrate inward terminals 112a, any sides of interconnect structures 150 (for example, distal ends, top sides, or lateral sides), and electronic component 120 including, for example, electronic component second side 122, lateral sides, portions of electronic component first side 121, portions of electronic component contact pads 123, or the lateral sides of connectors 124). In some examples, encapsulant 140 can cover the inner side of substrate 110 (for example, any dielectric or conductive structures exposed on the uppermost side of substrate 110). Encapsulant 140 can fully or partially cover the lateral sides of electronic component 120 (or a plurality of electronic components) or the lateral sides of the interconnect structures 150. In the present example, the sidewalls of interconnect structures 150 are embedded inside of encapsulant 140 and are not exposed from encapsulant 140.

In some examples, encapsulant 140 can also provide an underfill for electronic component 120, or a separate underfill can be applied during or after attachment of electronic component 120. The separate underfill can comprise capillary underfill (CUF), non-conductive paste (NCP), non-conductive film (NCF), anisotropic conductive film (ACF), anisotropic conductive paste (ACP), epoxy, or a molding compound. The underfill can be made of any of various types of materials, such as epoxy, a thermoplastic material, a thermosetting material, polyimide, polyurethane, polymeric material, filled epoxy, a filled thermoplastic material, a filled thermosetting material, filled polyimide, filled polyurethane, a filled polymer material, and fluxing underfill. The underfilling can be performed using a capillary underfill process by using pre-applied underfill.

In some examples, the underfill can be located between the inner side of substrate 110 and electronic component first side 121 of electronic component 120. The underfill can be in contact with electronic component 120 and the inner side of substrate 110. When the underfill includes a molded underfill (MUF), electronic component 120 can be covered by encapsulant 140 and the underfill can be considered a part of encapsulant 140. In some examples, when the underfill includes CUF, the space between electronic component 120 and substrate 110 can be filled with surface tension by spraying an underfill material through a thin capillary.

FIG. 2D shows a cross-sectional view of electronic device 100 at a later stage of manufacture. In the example shown in FIG. 2D, shield 160 can be provided on encapsulant 140 and the upper sides or distal ends of interconnect structures 150. In some examples, shield 160 can be a substantially flat and conformal structure. In some examples, shield 160 can connect interconnect structures 150 to each other, thereby shielding electronic component 120. In some examples, electronic device 100 can comprise interconnect structures 150 located on the lateral sides of electronic component 120 and shield 160. In some examples, shield 160 can connect interconnect structures 150 to each other on the upper side of electronic component 120. In this way, shield 160 can shield the uppermost and side portions of electronic component 120 and can be, for example, in a cap shape. In some examples, shield 160 can provide shielding for each electronic component 120. In some examples, shield 160 can be provided over encapsulant 140 using back side (BS) sputtering. Shield 160 can comprise or be referred to as a top shield or an upper shield structure and is provided without overlapping onto the lateral sides of encapsulant 140.

In some examples, interconnect structures 150 and shield 160 can reduce the effects of electromagnetic waves generated by electronic component 120 radiated external to electronic device 100. In some examples, interconnect structures 150 and shield 160 can reduce the effects of externally applied electromagnetic waves on electronic component 120. In some examples, such functions of interconnect structures 150 and shield 160 can be referred to as EMI shielding.

In some examples, shield 160 can be formed by using various conductive materials, such as copper (Cu), nickel (Ni), gold (Au), silver (Ag), platinum (Pt), cobalt (Co), titanium (Ti), chromium (Cr), zirconium (Zr), molybdenum (Mo), ruthenium (Ru), hafnium (Hf), tungsten (W), rhenium (Re), graphite (graphite), or carbon black. In other examples, shield 160 can comprise a conductive polymer such as polyacetylene, polyaniline, polypyrrole, polythiophene, or poly-sulfur-nitride doped with a metal or metal oxide. In other examples, shield 160 can comprise conductive ink with conductive materials such as carbon black, graphite, or silver.

In some examples, the thickness of shield 160 can range from approximately 0.1 microns to approximately 1000 microns. In some examples, the thickness of shield 160 can range from approximately 1.0 micron to approximately 100 microns. In some examples, the thickness of shield 160 can range from approximately 3 microns to approximately 30 microns. In some examples, if the thickness of shield 160 is less than approximately 0.1 microns, the EMI shielding efficiency of shield 160 can be less than a desired threshold, and if the thickness of shield 160 is greater than approximately 1,000 microns, the manufacturing cycle time to provide shield 160 can become too long to be economically feasible. In some examples, shield 160 can be referred to, for example, as an EMI shield, lid, or conformal metal coating. Shield 160 can be formed by spraying or sputtering and can also be configured as a heat dissipation shield. In the present example, shield 160 can be provided only on the top side of encapsulant 140 while electronic device 100 is part of a panel of electronic devices and additional shielding material is no longer required after the panel of electronic device is singulated into individual devices. This simplifies the manufacturing process and reduces the footprint of electronic device 100.

FIG. 2E shows a cross-sectional view of electronic device 100 at a later stage of manufacture. In the example shown in FIG. 2E, carrier 10 has been removed. In some examples, the temporary bonding layers can also be removed. In an example implementation, film substrate 20 and carrier 30 can be coupled or bonded to shield 160 (for example, on the opposite side of carrier 10), and carrier 10 and the temporary bonding layers can then be removed. In some examples, film substrate 20 can comprise a protective film or tape and carrier 30 can comprise a glass substrate or a glass wafer. In other examples, carrier 30 can be similar to the material of carrier 10.

In some examples, after film substrate 20 and carrier 30 are coupled to shield 160, heat, light, a chemical solution, or physical external force is applied to electronic device 100 to remove or reduce the adhesive force of the temporary bonding layer interposed between carrier 10 and substrate 110, carrier 10 can be separated from the lower side of substrate 110. The temporary bonding layer of carrier 10 can be separated from substrate 110 while being attached to carrier 10. Carrier 10 can be removed to expose the part of substrate 110. In some examples, carrier 10 and the temporary bonding layer can be removed in any of a variety of ways. For example, the temporary bonding layer can be released by applying energy (for example, heat energy or laser energy) to the temporary bonding layer or carrier 10. In some examples, carrier 10 can be peeled, cut or pulled away from the lower side of substrate 110. In some examples, carrier 10 or the temporary bonding layer can be ground (or polished) or chemically etched. Removal of carrier 10 and the temporary bonding layer can expose portions of dielectric structure 111 to the outside. After carrier 10 is removed, any necessary cleaning of substrate 110 can be done to remove any residual unwanted materials.

In the example shown in FIG. 2E, external interconnects 170 can be provided to the outer side of substrate 110. In some examples, external interconnects 170 can be connected to substrate outward terminals 112b. In some examples, external interconnects 170 can be in contact with and be electrically connected to substrate outward terminals 112b of substrate 110. In some examples, external interconnects 170 can be referred to as external input/output terminals of electronic device 100. External interconnects 170 can be electrically connected to electronic component 120 through the signal distribution structure of substrate 110. In some examples, external interconnects 170 can be ball-grid arrayed or land-grid arrayed on the outer side of substrate 110.

In some examples, external interconnects 170 can comprise conductive balls, bumps, solder balls, solder bumps, wafer bumps, solid core or copper core solder balls, conductive pillars such as copper pillars, of conductive posts with a solder cap formed on copper pillars. In some examples, external interconnects 170 can comprise tin (Sn), silver (Ag), lead (Pb), copper (Cu), Sn—Pb, Sn₃₇—Pb, Sn₉₅—Pb, Sn—Pb—Ag, Sn—Pb—Bi, Sn—Cu, Sn—Ag, Sn—Au, Sn—Bi, Sn—Ag—Cu, Sn—Ag—Bi, Sn—Zn, Sn—Zn—Bi, or combinations of tin, silver, lead, Sn—Pb, Sn₃₇—Pb, Sn₉₅—Pb, Sn—Pb—Ag, Sn—Pb—Bi, Sn—Cu, Sn—Ag, Sn—Au, Sn—Bi, Sn—Ag—Cu, Sn—Ag—Bi, Sn—Zn, Sn—Zn—Bi. In other examples, external interconnects 170 can also comprise conductive pillars or posts, wires, lands, or pads, and can comprise a plurality of conductive materials (for example, a metal or a conductive adhesive).

In some examples, external interconnects 170 can be provided by forming a conductive material containing solder on substrate outward terminals 112b through a ball drop method and then performing a reflow process. In some examples, the sizes of external interconnects 170 can range from approximately 25 microns to approximately 1000 microns.

External interconnects 170 can be configured in any or various configurations. For example, external interconnects 170 can be placed, for example, around an electronic device (or package) (for example, surrounding the footprint (or outline) of electronic component 120). In some examples, where at least a portion of the matrix/array is within the footprint of electronic component 120, external interconnects 170 can be arranged in a row/column matrix array.

In some examples, an additional component (for example, a passive component or an active component) can be provided on the outer side of substrate 110 and laterally between external interconnects 170. In some examples, with the additional component included electronic device 100 can be configured as a double-sided molded ball grid array (DSMBGA) package. The additional component can be molded or assembled in various configurations, such as a die-size ball grid array (DSBGA), or a wafer chip scale package (WCSP), and can be on both sides of the substrate. In an example implementation, the additional component can have a height less than external interconnects 170. In some examples, external interconnects 170 can provide standoffs to maintain spaces for the additional components.

FIG. 2F shows a cross-sectional view of electronic device 100 at a later stage of manufacture. In some examples, carrier 30 can be separated while leaving film substrate 20 in place. In some examples, if film substrate 20 is not configured for a singulation process, a singulation substrate 155, such as a singulation tape can be applied to film substrate 20. In other examples, film substrate 20 can be configured as a singulation substrate. In the present example, electronic device 100 can be provided as a plurality of electronic devices 100 in wafer, panel, or substrate form.

In the example shown in FIG. 2F, the panel of electronic devices 100 can flipped over and the panel of electronic devices can be singulated through substrate 110, encapsulant 140, and shield 160 to provide individual electronic devices 100. In some examples, the singulation process does not extend through singulation substrate 155, which leaves the individual electronic devices 100 attached to singulation substrate 155 for subsequent processing, such as a pick-and-place process.

The singulation can be performed any one or more of, for example, mechanical cutting (for example sawing, cutting, polishing or snapping), energy cutting (for example laser cutting or plasma cutting), or wet or dry chemical cutting (for example etching or dissolution). In an example implementation, the singulation can form coplanar lateral sides of an electronic device (or a package). In accordance with the present description, after singulation one or more lateral sides of substrate 110, shield 160, and encapsulant 140 can be coplanar on one or more lateral sides of electronic device 100.

FIG. 2G is a cross-sectional view showing electronic device 100 according to various aspects of the present disclosure. In some examples, after removing singulation substrate 155 or film substrate 20, a finished or near-finished electronic device 100 can be provided. In the example shown in FIG. 2G, electronic device 100 can individually shield electronic components 120 through interconnect structures 150 and shield 160. In some examples, shield 160 can couple interconnect structures 150 together at the upper ends or distal ends of the interconnect structures 150. In accordance with the present description, shield 160 can be provided without additional plating and reconstruction processes, which eliminates several process steps compared to prior approaches to forming shield structures.

In some examples, the implications of package edge exclusion requirements of previous package structures, such as keep-out zones of electronic device 100 (or package) can be minimized by applying a wafer-level shield rather than a can-level shield, which typically comprise physical metal enclosures that add weight and bulk to the package, increase manufacturing complexity and cost, and limit package size reduction. In accordance with the present description, electronic device 100 does not require a reconstruction process or a sputtering process to provide side shielding, which instead is provided by interconnect structures 150. Among other things, this reduces manufacturing steps, complexity, and cost.

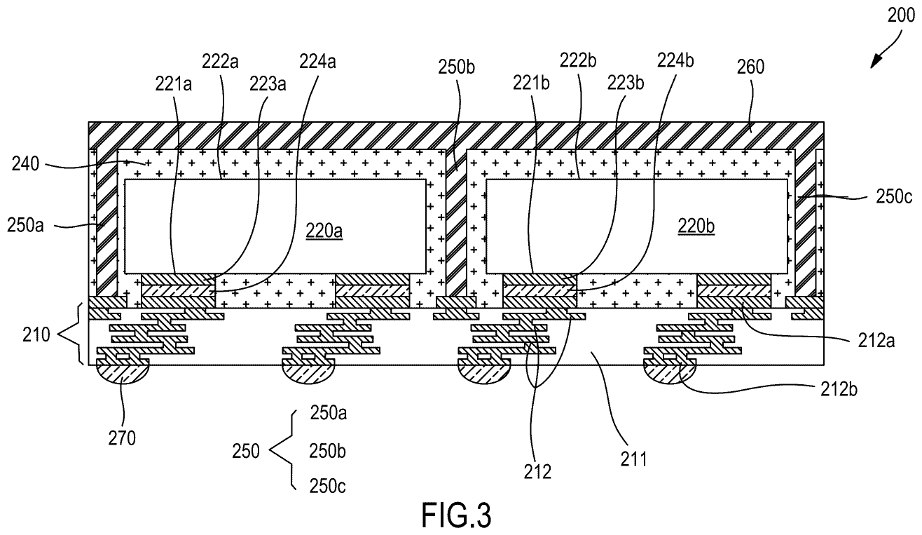

FIG. 3 shows a cross-sectional view of electronic device 200. In the present example, electronic device 200 can be similar to the structure and manufacturing method of electronic device 100 shown in FIG. 1 and FIGS. 2A-2G. However, it is understood that other methods or steps, such as the addition or removal of components, can be performed to provide electronic device 200. In the present example, electronic device 200 is configured with, among other things, multiple electronic components 220a and 220b. Electronic device 200 can be referred to as a semiconductor package, an electronic device, an electronic package, a device, or a package. In some examples, electronic device 200 can comprise substrate 210, first electronic component 220a, second electronic component 220b, encapsulant 240, multiple interconnect structures 250 including first interconnect structure 250a, second interconnect structure 250b, third interconnect structure 250c, shield 260, and external interconnects 270.

In some examples, substrate 210 can comprise dielectric structure 211 and conductive structure 212. Conductive structure 212 can comprise substrate inward terminals 212a at an inner side or top side of substrate 210, and substrate outward terminals 212b at an outer side or bottom side of substrate 210. First electronic component 220a can be coupled to the inner side of substrate 210 and can comprise first electronic component first side 221a, first electronic component second side 222a, first electronic component contact pad 223a, and first connectors 224a. In some examples, second electronic component 220b can be coupled to the inner side of substrate 210 and can comprise second electronic component first side 221b, second electronic component second side 222b, second electronic component contact pad 223b, and second connectors 224b.

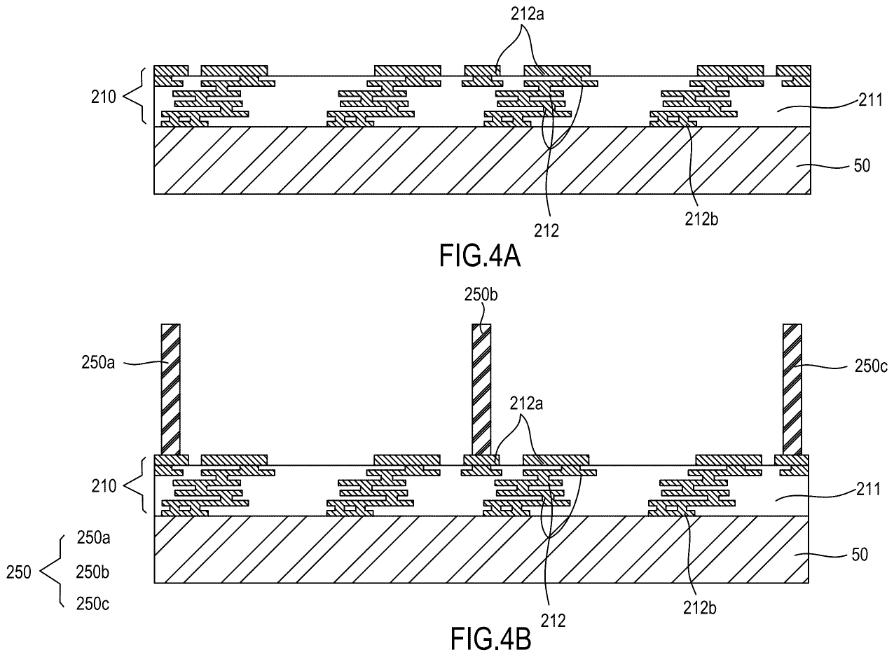

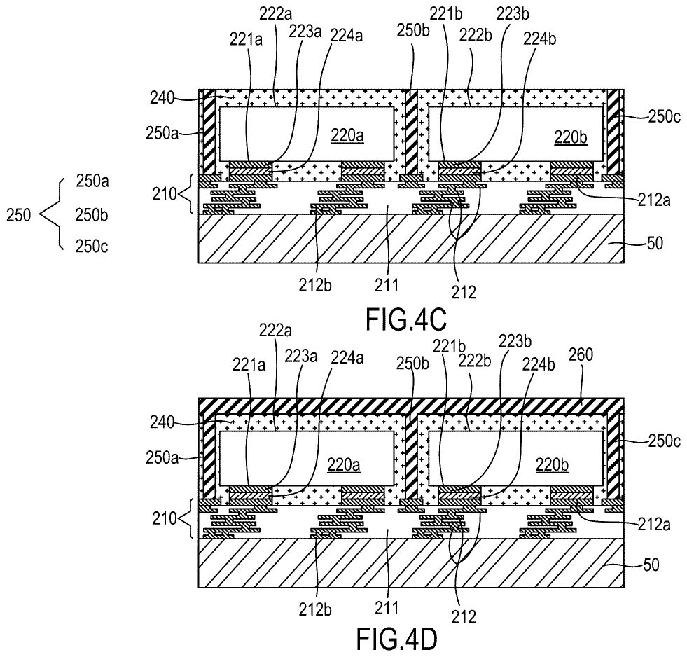

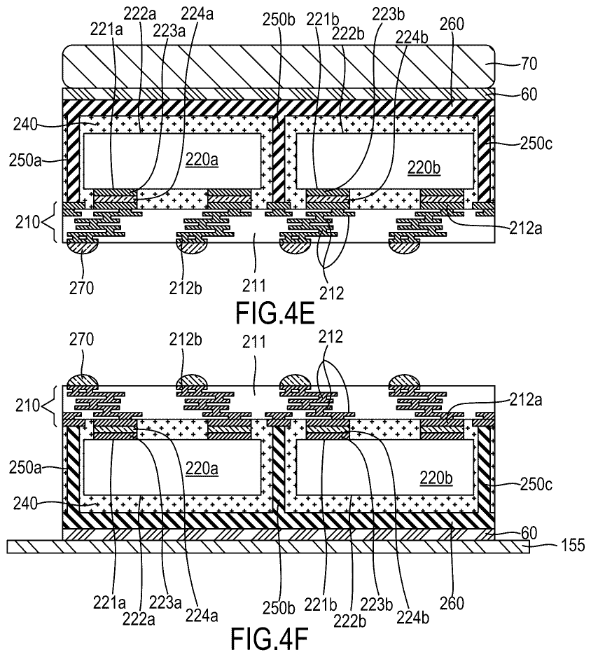

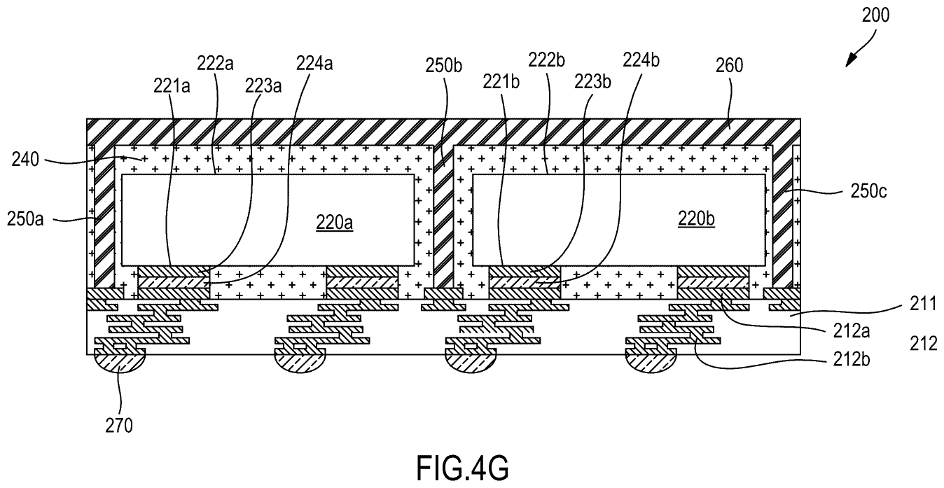

FIGS. 4A, 4B, 4C, 4D, 4E, 4F, and 4G are cross-sectional views showing various electronic device manufacturing methods, according to various aspects of the present description, and be used to provide electronic device 200. FIG. 4A shows a cross-sectional view of electronic device 200 at an early stage of manufacture. In the example shown in FIG. 4A, carrier 50 can be provided and substrate 210 can be provided on the upper side of carrier 50. In some examples, carrier 50 and substrate 210 of electronic device 200 can be similar to carrier 10 and substrate 110 of electronic device 100.

FIG. 4B shows a cross-sectional view of electronic device 200 at a later stage of manufacture. In the example shown in FIG. 4B, first interconnect structure 250a, second interconnect structure 250b, and third interconnect structure 250c can be coupled (or provided, attached, or formed) to the upper side or inner side of substrate 210. In some examples, first interconnect structure 250a, second interconnect structure 250b, and third interconnect structure 250c of electronic device 200 can be similar to interconnect structures 150 of electronic device 100. In the present example, proximate ends of interconnect structures 250a, 250b, and 250c are adjacent to the inner side of substrate 110 and distal ends of interconnect structures 250a, 250b, and 250c are space above or away from the inner side of substrate 110. First interconnect structure 250a, second interconnect structure 250b, and third interconnect structure 250c can comprise or be referred to as conductive pillars or pillar structures.

FIG. 4C shows a cross-sectional view of electronic device 200 at a later stage of manufacture. In the example shown in FIG. 4C, first electronic component 220a and second electronic component 220b can be coupled to the inner side of substrate 210. In some examples, three interconnect structures 250 and two electronic components 220a and 220b can be provided. In other examples, more than three interconnect structures 250 and more than two electronic components can be provided. First interconnect structure 250a, second interconnect structure 250b, and third interconnect structure 250c can comprise or be referred to as conductive pillars or pillar structures.

In some examples, after providing first interconnect structure 250a, second interconnect structure 250b, and third interconnect structure 250c, first electronic component 220a and second electronic component 220b can be provided on the inner side of substrate 210. In some examples, first interconnect structure 250a, second interconnect structure 250b, and third interconnect structure 250c can be in contact with and be electrically connected to substrate inward terminals 212a. First interconnect structure 250a, second interconnect structure 250b, and third interconnect structure 250c can be laterally spaced apart from first electronic component 220a and second electronic component 220b. In some examples, the heights of first interconnect structure 250a, second interconnect structure 250b, and third interconnect structure 250c can be greater than the thicknesses of first electronic component 220a and second electronic component 220b.

In some examples, first interconnect structure 250a, second interconnect structure 250b, and third interconnect structure 250c can be located at the center between and on both sides based on first electronic component 220a and second electronic component 220b respectively. For example, second interconnect structure 250b can be provided between first electronic component 220a and second electronic component 220b, and first interconnect structure 250a and third interconnect structure 250c can be provided on the side portions of first electronic component 220a and second electronic component 220b, respectively.

Accordingly, a shielding structure can be individually provided for each of first electronic component 220a and second electronic component 220b. In some examples, first interconnect structure 250a, second interconnect structure 250b, and third interconnect structure 250c can be provided to be spaced apart from first electronic component 220a and second electronic component 220b and provided along or around the perimeter of first electronic component 220a and second electronic component 220b. In some examples, first interconnect structure 250a, second interconnect structure 250b, and third interconnect structure 250c can provide EMI shielding for first electronic component 220a and second electronic component 220b. In some examples, first electronic component 220a and second electronic component 220b can be similar to the electronic component 120 of the electronic device 100.

In the example shown in FIG. 4C, encapsulant 240 can be provided to cover the inner side of substrate 210, first interconnect structure 250a, second interconnect structure 250b, third interconnect structure 250c, first electronic component 220a, and second electronic component 220b. In some examples, the top portion of encapsulant 240 can be removed to expose the top portions or distal ends of first interconnect structure 250a, second interconnect structure 250b, and third interconnect structure 250c. In some examples, the top portion of encapsulant 240 can be removed by grinding, polishing, etching, or combinations thereof. In some examples, when the top portion of encapsulant 240 is removed, the top portions of first interconnect structure 250a, second interconnect structure 250b, and third interconnect structure 250c can also be removed to define the distal ends of these structures. In some examples, the upper side of encapsulant 240 can be substantially coplanar with the upper sides or distal ends of first interconnect structure 250a, second interconnect structure 250b, and third interconnect structure 250c. In some examples, the thickness of encapsulant 240 and the heights of first interconnect structure 250a, second interconnect structure 250b, and third interconnect structure 250c can be similar. Encapsulant 240 can be in contact with the inner side of substrate 210 and the sidewalls of first interconnect structure 250a, second interconnect structure 250b, and third interconnect structure 250c. In the present example, the sidewalls of first interconnect structure 250a, second interconnect structure 250b, and third interconnect structure 250c are embedded inside of encapsulant 240 and are not exposed from encapsulant 240. In some examples, encapsulant 240 of electronic device 200 can be similar to encapsulant 140 of electronic device 100.

FIG. 4D shows a cross-sectional view of electronic device 200 at a later stage of manufacture. In the example shown in FIG. 4D, shield 260 can be provided on encapsulant 240 and the upper sides or distal ends of first interconnect structure 250a, second interconnect structure 250b, and third interconnect structure 250c. In some examples, shield 260 can connect first interconnect structure 250a, second interconnect structure 250b, and third interconnect structure 250c to one another, thereby shielding first electronic component 220a and second electronic component 220b. In some examples, first interconnect structure 250a, second interconnect structure 250b, third interconnect structure 250c, and shield 260 can reduce the effects of electromagnetic waves generated from first electronic component 220a and second electronic component 220b from being radiated. In some examples, first interconnect structure 250a, second interconnect structure 250b, third interconnect structure 250c, and shield 260 can reduce the effects of externally applied electromagnetic waves from entering first electronic component 220a and second electronic component 220b. In some examples, shield 260 of electronic device 200 can be similar to shield 160 of electronic device 100. Shield 260 can comprise or be referred to as a top shield or an upper shield structure and is provided without overlapping onto the lateral sides of encapsulant 240. In some examples, shield 260 of electronic device 200 can be similar to shield 160 of electronic device 100.

FIG. 4E shows a cross-sectional view of electronic device 200 at a later stage of manufacture. In the example shown in FIG. 4E, carrier 50 has been removed. In some examples, the temporary bonding layer can also be removed. In an example implementation, film substrate 60 and carrier 70 can be coupled to or bonded to shield 260 (for example, on the opposite side of carrier 50), and carrier 50 and the temporary bonding layer can then be removed as described previously with carrier 10. In some examples, film substrate 60 and carrier 70 of electronic device 200 can be similar to film substrate 20 and carrier 30 of electronic device 100.

In some examples, referring to electronic device 200 of FIG. 4E, external interconnects 270 can be provided on the outer side or bottom side of substrate 210. In some examples, a plurality of external interconnects 270 can be provided and can be connected to substrate outward terminals 212b. In some examples, external interconnects 270 of electronic device 200 can be similar to external interconnects 170 of electronic device 100.

FIG. 4F shows a cross-sectional view of electronic device 200 at a later stage of manufacture. In some examples, carrier 70 can be separated while leaving film substrate 60 in place. In some examples, if film substrate 60 is not configured for a singulation process, a singulation substrate 155, such as a singulation tape can be applied to film substrate 60. In the present example, electronic device 200 can be provided as a plurality of electronic devices 200 in wafer, panel, or substrate form.

In the example shown in FIG. 2F, the panel of electronic devices 200 can flipped over and the panel of electronic devices can be singulated through substrate 210, then through encapsulant 240, and then through shield 260 to provide individual electronic devices 200. In some examples, the singulation method of electronic device 200 can be similar to the singulation method of electronic device 100.

FIG. 4G is a cross-sectional view of electronic device 200 at a later stage of manuafcture. In some examples, after removing film substrate 60, a finished or near-finished electronic device 200 can be provided.

In the example shown in FIG. 4G, electronic device 200 can individually shield first electronic component 220a and second electronic component 220b through first interconnect structure 250a, second interconnect structure 250b, and third interconnect structure 250c. In some examples, electronic device 200 can individually shield first electronic component 220a and second electronic component 220b through shield 260. In some examples shield 260 can couple first interconnect structure 250a, second interconnect structure 250b, and third interconnect structure 250c together at the distal ends of first interconnect structure 250a, second interconnect structure 250b, and third interconnect structure 250c. In accordance with the present description, shield 260 can be provided without additional plating and reconstruction processes, which eliminates several process steps compared to prior approaches to forming shield structures.

In some examples, the implications of package edge exclusion requirements of previous package structures, such as keep-out zones, of electronic device 200 (or package) can be minimized by applying a wafer-level shield rather than a can-level shield. In accordance with the present description, electronic device 200 does not require a reconstruction process or a sputtering process to provide side shielding, which instead is provided by interconnect structures 250. Among other things, this reduces manufacturing steps, complexity, and cost.

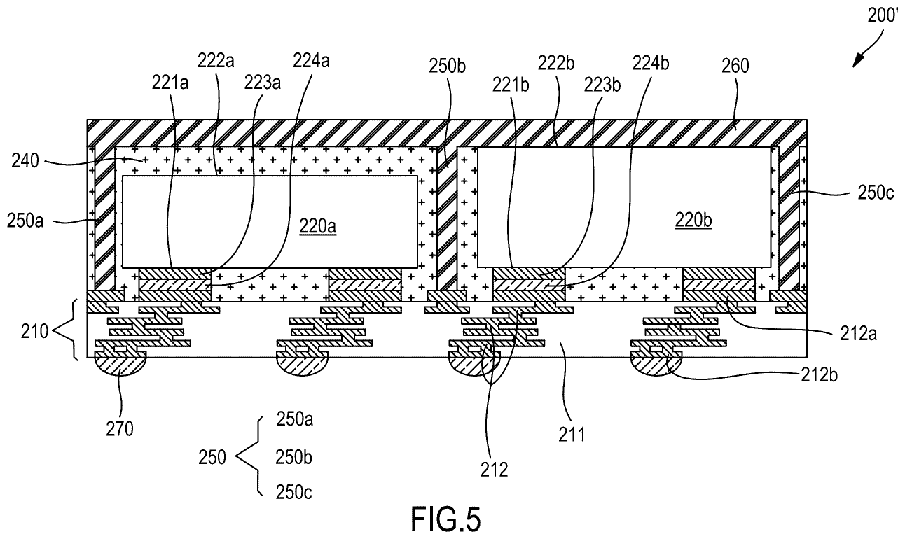

In accordance with the present description, first interconnect structure 250a, second interconnect structure 250b, and third interconnect structure 250c, or external interconnects 270 can be arranged in any of a variety of configurations. As shown in FIGS. 3, 5, and 6, in some examples, first interconnect structure 250a, second interconnect structure 250b, and third interconnect structure 250c can be disposed around the perimeter of the footprints (or outlines) of first electronic component 220a and second electronic component 220b. In some examples, there can be a matrix of external interconnects 270 where the signal distribution structure of substrate 210 provides a fan-in configuration to locations within the footprints (or outlines) of first electronic component 220a and second electronic component 220b. For example, as shown in FIGS. 3 and 5, at least some of external interconnects 270 can be positioned below first electronic component 220a and second electronic component 220b.

FIG. 5 shows a cross-sectional view of an example electronic device 200′. Electronic device 200′ can be similar to the structure and manufacturing method of electronic device 200 shown in FIG. 3. However, it is understood that other methods or steps, such as addition or removal of components, can be performed to manufacture electronic device 200′. In the example shown in FIG. 5, the heights of first electronic component 220a and second electronic component 220b can be different. In some examples, second electronic component 220b can be thicker than first electronic component 220a and can be coupled to shield 260. In some examples, second electronic component second side 222b of second electronic component 220b can be in contact with shield 260.

In some examples, second electronic component 220b can be disposed within encapsulant 240, and then second electronic component second side 222b can be exposed by removing an upper portion of encapsulant 240. In some examples, this can be done while exposing the distal ends of interconnect structures 250a, 250b, and 250c. Shield 260 can then be provided coupled to second electronic component second side 222b of second electronic component 220b. In this configuration, coupling between shield 260 and second electronic component 220b can allow heat to transfer without passing through encapsulant 240, thereby reducing package thermal resistance while also enhancing EMI shielding performance. In some examples, a thermal interface material (TIM) can be provided between second electronic component second side 222b and shield 260 to improve adhesion between shield 260 and second electronic component 220b or to further enhance heat transfer.

In some examples, first electronic component 220a and shield 260 can be separated without contacting each other. A molding layer positioned between shield 260 and first electronic component 220a can absorb thermal and mechanical stress. In the present example, by using planar grinding to remove a portion of encapsulant 240 followed by deposition of only a top conductive film to provide shield 260 can simplify processing and enable a smaller package profile and footprint.

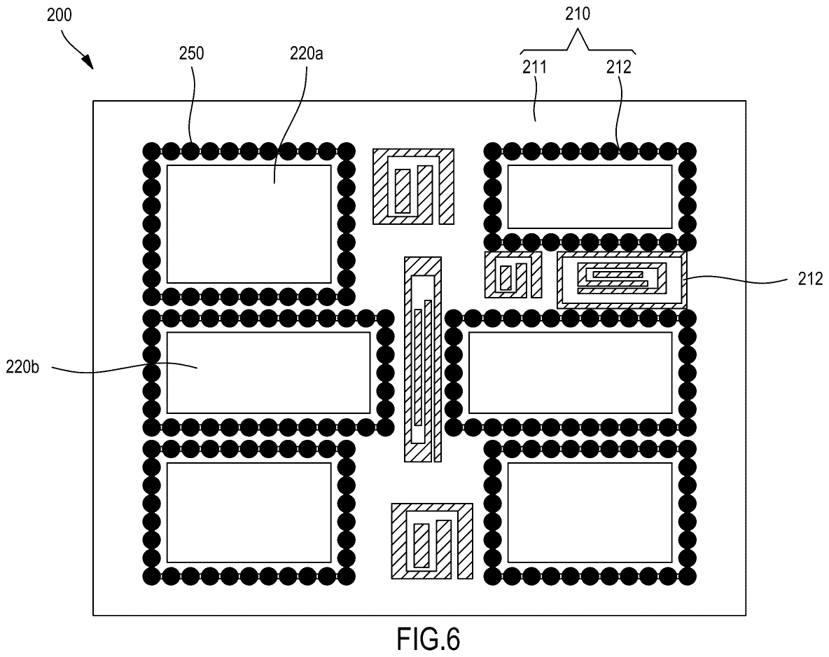

FIG. 6 shows a plan view of example electronic device 200. FIG. 3 shows an overall shield, and FIG. 6 shows a compartment. In some examples, FIG. 6 can be a plan view of electronic device 200 (or package) of FIG. 3. In the example shown in FIG. 6, first electronic component 220a and second electronic component 220b can be arranged in a matrix with rows and columns on substrate 210. In some examples, the numbers of first electronic component 220a and second electronic component 220b formed on substrate 210 can be more or less than the numbers of first electronic component 220a and second electronic component 220b shown in FIG. 6. In some examples, after first interconnect structure 250a, second interconnect structure 250b, third interconnect structure 250c, shield 260 are attached (coupled) at a later stage of manufacture, electronic device 200 arranged in a matrix or panel and can be covered or molded (for example, overmolded) by encapsulant 240 and singulated.

In some examples, depending on the shapes, sizes, and numbers of first electronic component 220a and second electronic component 220b, the shapes, sizes, and numbers of shielding areas can also be formed in various ways. In some examples, in electronic device 200, first interconnect structure 250a, second interconnect structure 250b, third interconnect structure 250c, and shield 260 can reduce the effects of electromagnetic waves generated by first electronic component 220a and second electronic component 220b from being radiated. In some examples, electronic device 200 can reduce externally applied electromagnetic waves from entering first electronic component 220a and second electronic component 220b through first interconnect structure 250a, second interconnect structure 250b, third interconnect structure 250c, and shield 260.

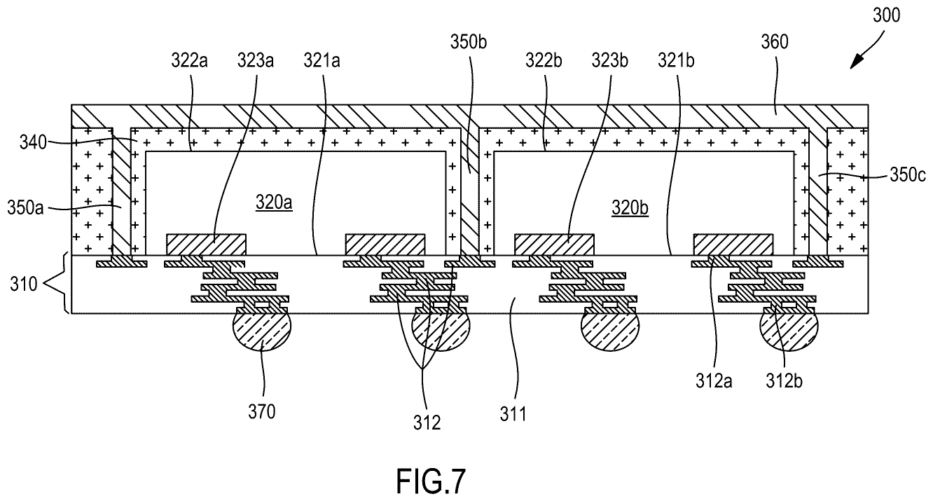

FIG. 7 shows a cross-sectional view of an example electronic device 300. In the present example, electronic device 300 can be similar to the structure and manufacturing method of electronic device 100 shown in FIG. 1. However, it is understood that other methods or steps, such as addition or removal of components, can be performed to manufacture electronic device 300. Electronic device 300 can be referred to as a semiconductor package, an electronic device, an electronic package, a device, or a package. Electronic device 300 can comprise substrate 310, first electronic component 320a, second electronic component 320b, encapsulant 340, first interconnect structure 350a, second interconnect structure 350b, third interconnect structure 350c, shield 360, and external interconnects 370.

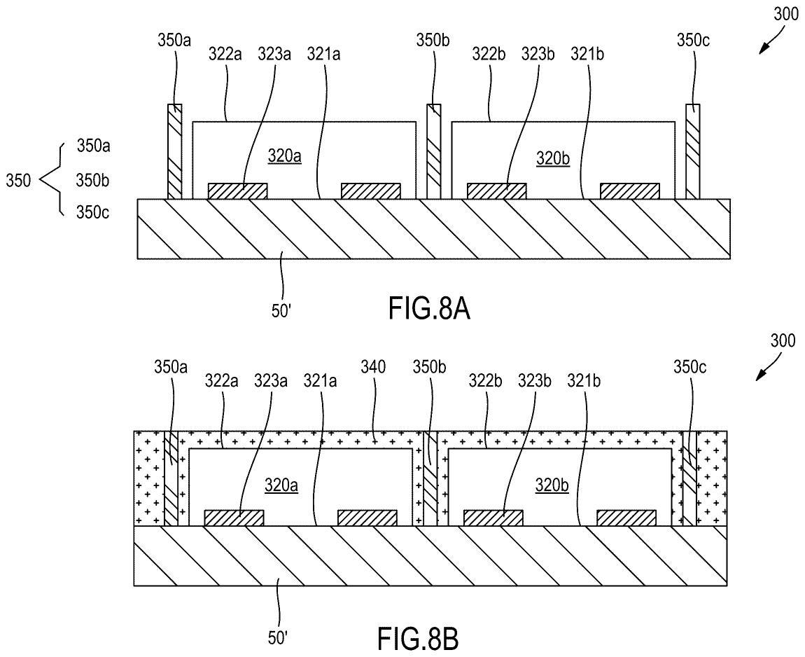

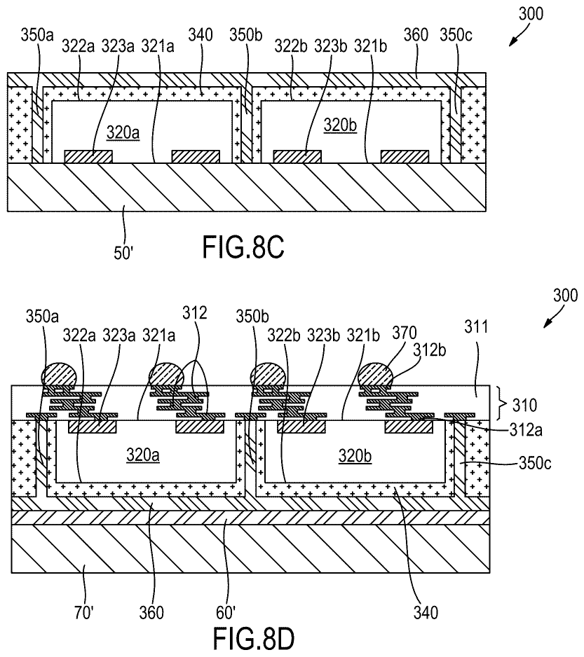

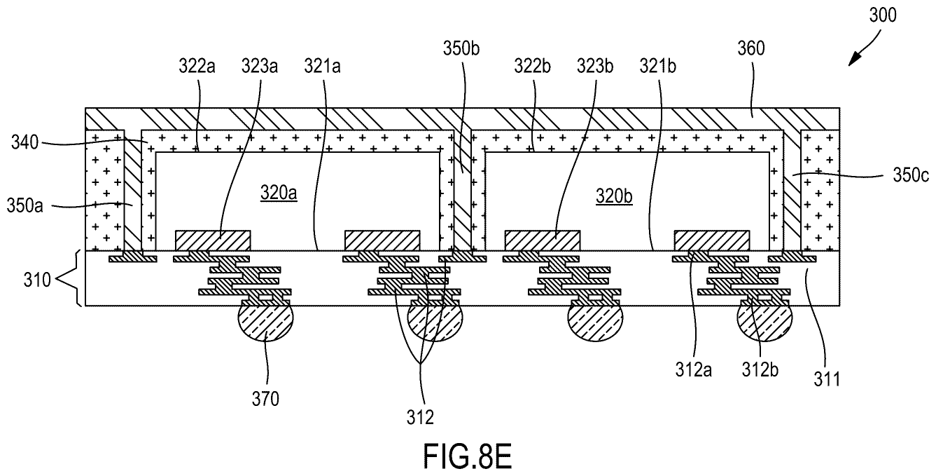

In some examples, substrate 310 can comprise dielectric structure 311 and conductive structure 312. Conductive structure 312 can comprise substrate inward terminals 312a and substrate outward terminals 312b. First electronic component 320a can comprise first electronic component first side 321a, first electronic component second side 322a, and first connectors 323a. In some examples, second electronic component 320b can comprise second electronic component first side 321b, second electronic component second side 322b, and second connectors 323b. In some examples, the elements described in FIGS. 7 and 8A-8E can be similar to any of the elements described in FIGS. 1-6.

FIGS. 8A, 8B, 80, 8D, and 8E are cross-sectional views showing various electronic device manufacturing steps, according to various aspects of the present description, which can be used to provide electronic device 300. This method can comprise or be referred to as a die or component first face-down process. This can include a plurality of structures configured as a wafer, panel, or substrate to be singulated into a plurality of electronic devices. In the present example, the electronic components and interconnect structures are provided in an early stage of fabrication, the encapsulant, and shield are then provided. The substrate and external interconnects are provided at a later stage of fabrication. In the present example, the shield (shield 360) is provided before the substrate (substrate 310) is provided. This can also be referred to as a shield first and substrate second method.

FIG. 8A shows a cross-sectional view of electronic device 300 at an early stage of manufacture. In the example shown in FIG. 8A, carrier 50′ can be provided. In some examples, first interconnect structure 350a, second interconnect structure 350b, and third interconnect structure 350c can be attached (or provided, coupled, or formed) on the upper side of carrier 50′. In the present example, the ends of interconnect structures 350a, 350b, and 350c that are attached to carrier 50′ can be referred to as proximate ends and the opposite ends of interconnect structures 350a, 350b, and 350c can be referred to as distal ends. In the present example, the proximate ends are adjacent to active sides of first electronic component 320a and second electronic component 320b.

In some examples, first interconnect structure 350a and third interconnect structure 350c can be respectively located on carrier 50′ adjacent opposite sides of electronic components 320a and 320b. In some examples, second interconnect structure 350b can be located on carrier 50′ between adjacent sides of electronic components 320b. In some examples, first electronic component 320a and second electronic component 320b can be coupled (including attached) to the upper side or inner side of carrier 50′. In some examples, more than three interconnect structures 350 and more than two electronic components 320a and 320b can be provided. In some examples, carrier 50′ is provided and then interconnect structures 350 and electronic components 320a and 320b are then coupled to carrier 50′ in either order or simultaneously. First interconnect structure 350a, second interconnect structure 350b, and third interconnect structure 350c can comprise or be referred to as conductive pillars or pillar structures.

In some examples, after providing first interconnect structure 350a, second interconnect structure 350b, and third interconnect structure 350c, first electronic component 320a and second electronic component 320b can be provided and coupled to the upper side or inner side of carrier 50′. In some examples, first electronic component first side 321a of first electronic component 320a and second electronic component first side 321b of second electronic component 320b can each comprise or be referred to as an active side, and the active side of first electronic component 320a and second electronic component 320b are placed adjacent to and facing the inner side of carrier 50′. In some examples, first electronic component 320a and second electronic component 320b are placed directly onto the temporary adhesive layer portion of carrier 50′ without any intervening conductive pattern or substrate.

In some examples, first interconnect structure 350a, second interconnect structure 350b, and third interconnect structure 350c can be formed of a wire or by plating. First interconnect structure 350a, second interconnect structure 350b, and third interconnect structure 350c can be laterally spaced apart from first electronic component 320a and second electronic component 320b. In some examples, the heights of first interconnect structure 350a, second interconnect structure 350b, and third interconnect structure 350c can be greater than or equal to the thicknesses of first electronic component 320a and second electronic component 320b as referenced from the inner side of carrier 50′. In some examples, first interconnect structure 350a, second interconnect structure 350b, and third interconnect structure 350c can be located at the center and on both sides based on first electronic component 320a and second electronic component 320b. For example, second interconnect structure 350b can be provided between first electronic component 320a and second electronic component 320b, and first interconnect structure 350a and third interconnect structure 350c can be provided on the side portions of first electronic component 320a and second electronic component 320b, respectively.

Accordingly, a shielding structure can be individually provided for each of first electronic component 320a and second electronic component 320b. In some examples, first interconnect structure 350a, second interconnect structure 350b, and third interconnect structure 350c can be provided along the perimeter of first electronic component 320a and second electronic component 320b. In some examples, EMI shielding including individual shielding can be provided for first electronic component 320a and second electronic component 320b. In some examples, carrier 50′ of electronic device 300 can be similar to carrier 10 of electronic device 100. In some examples, first interconnect structure 350a, second interconnect structure 350b, and third interconnect structure 350c of electronic device 300 can be similar to interconnect structures 150 of electronic device 100. In some examples, first electronic component 320a and second electronic component 320b of electronic device 300 can be similar to electronic component 120 of the electronic device 100.

FIG. 8B shows a cross-sectional view of electronic device 300 at a later stage of manufacture. In the example shown in FIG. 8B, encapsulant 340 can be provided over the inner side of carrier 50′. In some examples, encapsulant 340 can be provided to cover first electronic component 320a, second electronic component 320b, first interconnect structure 350a, second interconnect structure 350b, and third interconnect structure 350c. The top portion of encapsulant 340 can be removed to expose the upper sides or distal ends of first interconnect structure 350a, second interconnect structure 350b, and third interconnect structure 350c. In some examples, the top portion of encapsulant 340 can be removed by grinding, polishing, etching, or combinations thereof.

In some examples, when the top portion of encapsulant 340 is removed, the top portions of first interconnect structure 350a, second interconnect structure 350b, and third interconnect structure 350c can also be removed to define the distal ends of these interconnect structures. In some examples, the upper side of encapsulant 340 can be coplanar with the distal ends of first interconnect structure 350a, second interconnect structure 350b, and third interconnect structure 350c. In other examples, the distal ends of first interconnect structure 350a, second interconnect structure 350b, and third interconnect structure 350c can be recessed inward with respect to the upper side of encapsulant 340. In some examples, the thickness of encapsulant 340 and the heights of first interconnect structure 350a, second interconnect structure 350b, and third interconnect structure 350c can be similar as referenced from the upper side of carrier 50′.

In some examples, encapsulant 340 can be in contact with the inner side of carrier 50′, the sidewalls of first interconnect structure 350a, second interconnect structure 350b, and third interconnect structure 350c, and the sidewalls and the upper sides of first electronic component 320a and second electronic component 320b. In the present example, the sidewalls of first interconnect structure 350a, second interconnect structure 350b, and third interconnect structure 350c, and the sidewalls and the upper sides of first electronic component 320a and second electronic component 320b are embedded inside of encapsulant 340. In some examples, encapsulant 340 of electronic device 300 can be similar to encapsulant 140 of electronic device 100.

FIG. 8C shows a cross-sectional view of electronic device 300 at a later stage of manufacture. In the example shown in FIG. 8C, shield 360 can be provided on the upper sides or distal ends of first interconnect structure 350a, second interconnect structure 350b, and third interconnect structure 350c. In some examples, shield 360 can be provided over the top side of encapsulant 340. Shield 360 can couple first interconnect structure 350a, second interconnect structure 350b, and third interconnect structure 350c to one another, thereby shielding first electronic component 320a and second electronic component 320b. In some examples, first interconnect structure 350a, second interconnect structure 350b, third interconnect structure 350c, and shield 360 can reduce the effects of electromagnetic waves generated from first electronic component 320a and second electronic component 320b from being radiated. In some examples, first interconnect structure 350a, second interconnect structure 350b, third interconnect structure 350c, and shield 360 can reduce the effects of externally applied electromagnetic waves from entering first electronic component 320a and second electronic component 320b. In some examples, shield 360 of electronic device 300 can be similar to shield 160 of electronic device 100. Shield 360 can comprise or be referred to as a top shield and is provided without overlapping onto the lateral sides of encapsulant 340.

FIG. 8D shows a cross-sectional view of electronic device 300 at a later stage of manufacture. In the example shown in FIG. 8D, carrier 50′ has been removed. In some examples, the temporary bonding layer can also be removed. In an example implementation, film substrate 60′ and carrier 70′ can be coupled to or bonded to shield 360 (for example, on the opposite side of carrier 50′), and carrier 50′ and the temporary bonding layer can then be removed as described previously with carrier 10. In the present example, after carrier 50′ is removed, the proximate ends of first interconnect structure 350a, second interconnect structure 350b, third interconnect structure 350c, outer sides of first connectors 323a, and outer sides of second connectors 323b are exposed from encapsulant 340. In the present example, the proximate ends of first interconnect structure 350a, second interconnect structure 350b, third interconnect structure 350c, the outer sides of first connectors 323a, and the outer sides of second connectors 323b are substantially coplanar with the inner side of encapsulant 340. In the present example, shield 360 is oriented to be adjacent to the inner side of carrier 70′ and the active sides of first electronic component 320a and second electronic component 320b are oriented away from the inner side of carrier 70′. In some examples, film substrate 60′ and carrier 70′ of electronic device 300 can be similar to film substrate 20 and carrier 30 of electronic device 100.

In some examples, substrate 310 can then be provided at the location where carrier 50′ has been removed. In the present example, substrate 310 can be provided attached, coupled, or formed over the lower sides or proximate ends of first interconnect structure 350a, second interconnect structure 350b, and third interconnect structure 350c; over the lower side of encapsulant 340; and over the active sides of first electronic component 320a and second electronic component 320b. In some examples, substrate 310 comprises an RDL substrate that is formed or built-up layer by layer to provide individual layers of conductive structure 312 (including substrate inward terminals 312a and substrate outward terminals 312b) and individual layers of dielectric structure 311. In some examples, substrate inward terminals 312a can be provided connected to proximate ends of first interconnect structure 350a, second interconnect structure 350b, and third interconnect structure 350c, and connected to first connectors 323a and second connectors 323b exposed from encapsulant 340.

In some examples, after substrate 310 is provided, external interconnects 370 can be provided coupled to substrate outward terminals 312b of substrate 310. In some examples, a plurality of external interconnects 370 can be provided and can be connected to substrate outward terminals 312b. In some examples, substrate 310 and external interconnects 370 of electronic device 300 can be similar to substrate 110 and external interconnects 170 of electronic device 100.

FIG. 8E shows a cross-sectional view of electronic device 300 at a later stage of manufacture. In some examples, carrier 70′ can be separated while leaving film substrate 60′ in place. In some examples, film substrate 60′ can be used as a singulation substrate or an additional singulation substrate can be coupled to film substrate 60′, such as singulation substrate 155 described previously. In the present example, electronic device 300 can be provided as a plurality of electronic devices 300 in wafer, panel, or substrate form. In the present example, the panel of electronic devices 300 can be singulated through substrate 310, then through encapsulant 340, and then through shield 360 to provide individual electronic devices 300. In some examples, film substrate 60′ can be removed to provide a finished or near finished electronic device 300. In some examples, the singulation method of electronic device 300 can be similar to the singulation method of electronic device 100 or electronic device 200.

In the example shown in FIG. 8E, electronic device 300 can individually shield first electronic component 320a and second electronic component 320b through first interconnect structure 350a, second interconnect structure 350b, and third interconnect structure 350c. In some examples, electronic device 300 can individually shield first electronic component 320a and second electronic component 320b through shield 360. In some examples, shield 360 can interconnect first interconnect structure 350a, second interconnect structure 350b, and third interconnect structure 350c at the upper ends or distal ends of first interconnect structure 350a, second interconnect structure 350b, and third interconnect structure 350c. In accordance with the present description, shield 360 can be provided without additional plating and reconstruction processes, which eliminates several process steps compared to prior approaches to forming shield structures.

In some examples, the implications of package edge exclusion requirements of previous package structures, such as keep-out zones, of electronic device 300 (or package) can be minimized by applying a wafer-level shield rather than a can-level shield. In accordance with the present description, electronic device 300 does not require a reconstruction process or a sputtering process to provide side shielding, which instead is provided by interconnect structures 350. Among other things, this reduces manufacturing steps, complexity, and cost.

In accordance with the present description, first interconnect structure 350a, second interconnect structure 350b, and third interconnect structure 350c can be arranged in any of a variety of configurations including those illustrated in FIG. 6

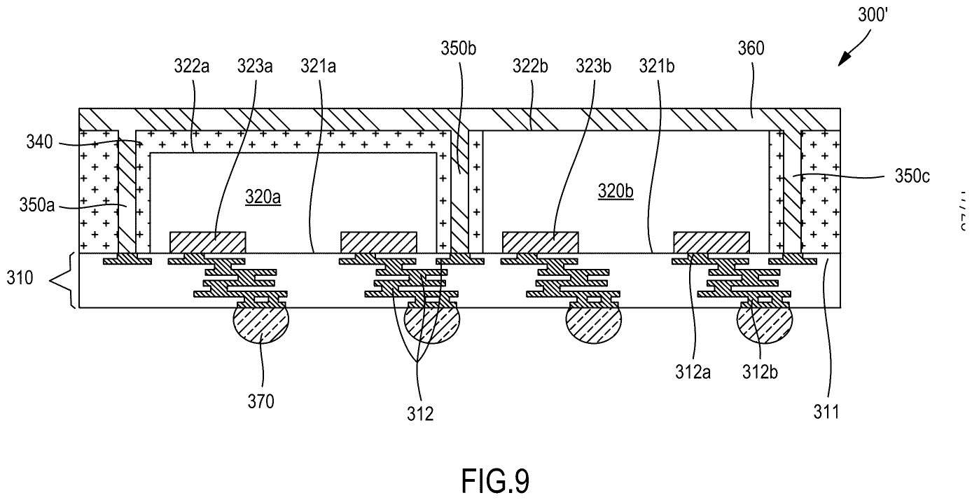

FIG. 9 shows a cross-sectional view of an example electronic device 300′. Electronic device 300′ can be similar to the structure and manufacturing method of electronic device 300 shown in FIG. 7. However, it is understood that other methods or steps, such as addition or removal of components, can be performed to manufacture electronic device 300′. In the example shown in FIG. 9, the heights or thicknesses of first electronic component 320a and second electronic component 320b can be different. In some examples, second electronic component 320b can be thicker than first electronic component 320a and can be coupled to shield 360. In some examples, second electronic component second side 322b of second electronic component 320b can be in contact with shield 360.

In some examples, second electronic component 320b can be disposed within encapsulant 340, and then second electronic component second side 322b of second electronic component 320b can be exposed by removing an upper portion of encapsulant 340. In some examples, this can be done while exposing the distal ends of interconnect structures 350a, 350b, and 350c. Shield 360 can be then provided to contact second electronic component second side 322b of second electronic component 320b. In this configuration, coupling between shield 360 and second electronic component 320b can allow heat to transfer without passing through encapsulant 340, thereby reducing package thermal resistance while also enhancing EMI shielding performance. In some examples, a thermal interface material (TIM) can be provided between second electronic component second side 322b and shield 360 to improve adhesion between shield 360 and second electronic component 320b or to further enhance heat transfer.

In some examples, first electronic component 320a and shield 360 can be separated without contacting each other. The portion of encapsulant 340 interposed between shield 360 and first electronic component 320a can absorb thermal and mechanical stress. In the present example, by using planar grinding to remove a portion of encapsulant 340 followed by deposition of only a top conductive film to provide shield 360 can simplify processing and enable a smaller package profile and footprint.

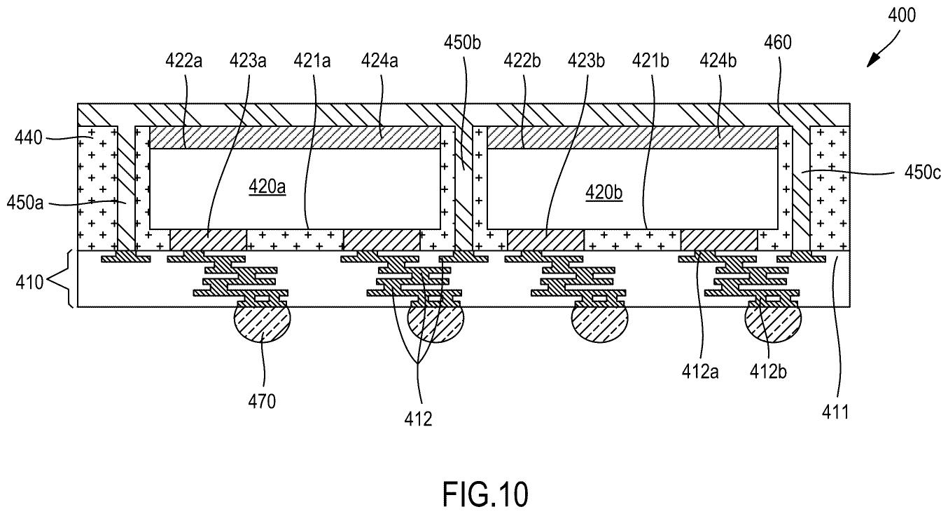

FIG. 10 shows a cross-sectional view of an example electronic device 400. In the present example, electronic device 400 can be similar to the structure and manufacturing method of electronic device 100 shown in FIG. 1 and electronic device 300 shown in FIG. 7. However, it is understood that other methods or steps, such as addition or removal of components, can be performed to provide electronic device 400. Electronic device 400 can be referred to as a semiconductor package, an electronic device, an electronic package, a device, or a package. Electronic device 400 can comprise substrate 410, first electronic component 420a, second electronic component 420b, encapsulant 440, first interconnect structure 450a, second interconnect structure 450b, third interconnect structure 450c, shield 460, and external interconnects 470.

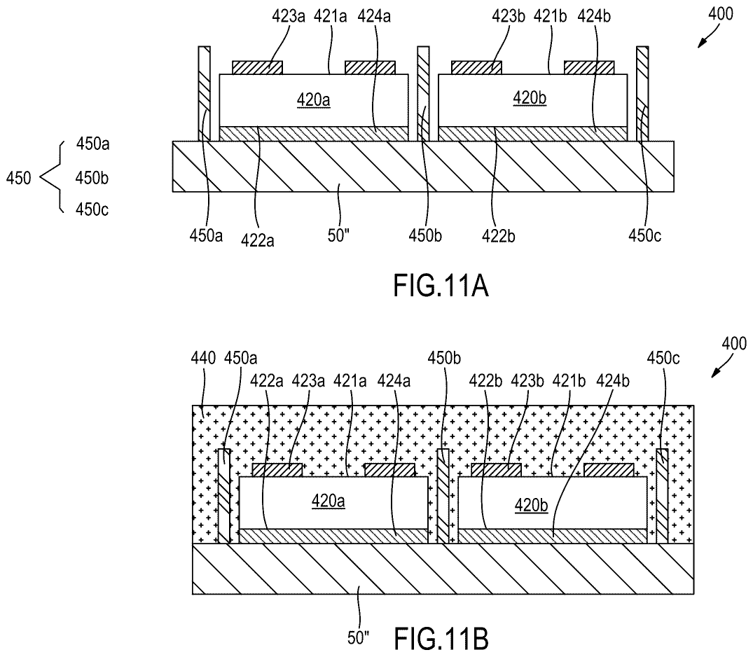

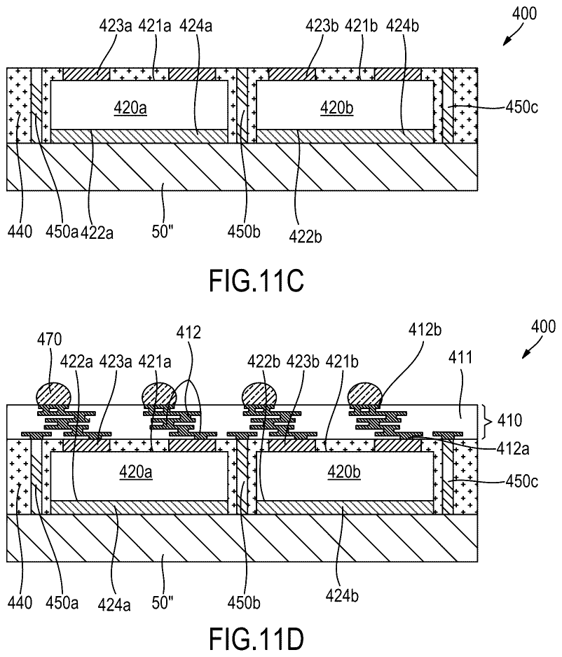

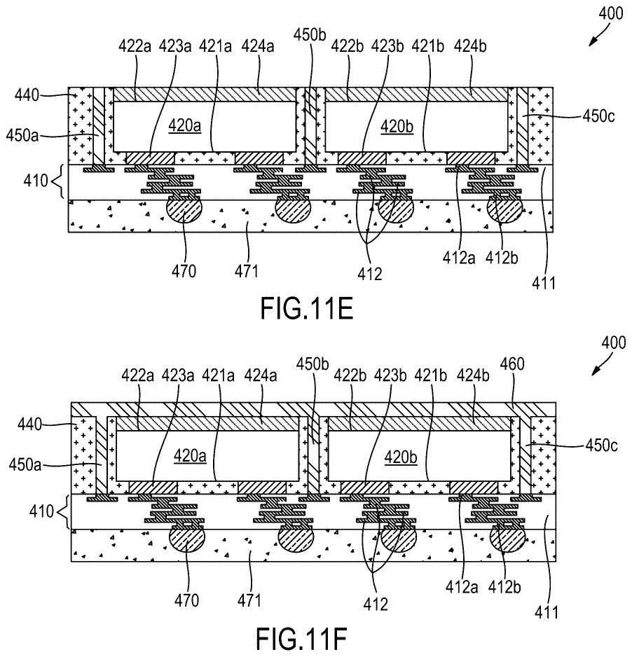

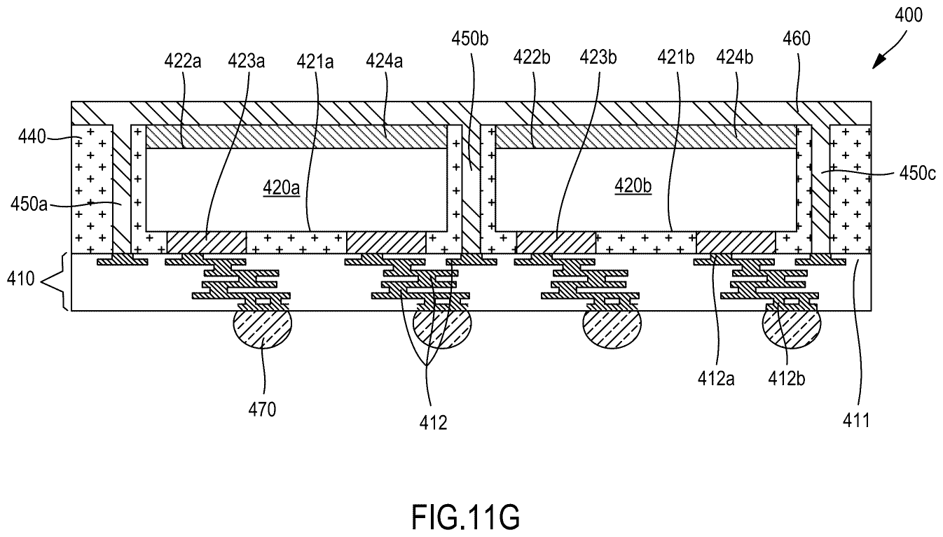

In some examples, substrate 410 can comprise dielectric structure 411 and conductive structure 412. Conductive structure 412 can comprise substrate inward terminals 412a and substrate outward terminals 412b. First electronic component 420a can comprise first electronic component first side 421a, first electronic component second side 422a, first connectors 423a, and first electronic component contact pad 424a. In some examples, second electronic component 420b can comprise second electronic component first side 321b, second electronic component second side 422b, second connectors 423b, and second electronic component contact pad 424b. Any elements described in FIGS. 10 and 11A-11G can be similar to any of the elements described in FIGS. 1-9.

FIGS. 11A, 11B, 11C, 11D, 11E, 11F, and 11G are cross-sectional views showing various electronic device manufacturing steps, according to various aspects of the present disclosure, which can be used to provide electronic device 400. This method can comprise or be referred to as a die or component first face-up process. This can include a plurality of structures configured as a wafer or panel to be singulated into a plurality of electronic devices. In the present example, the electronic components and interconnect structures are provided in an early stage of fabrication, and the encapsulant is then provided. The substrate, the external interconnects, and the shield are then provided at a later stage of fabrication. In the present example, the substrate (substrate 410) is provided before the shield (shield 460) is provided. This can also be referred to as a substrate first and shield second method.

FIG. 11A shows a cross-sectional view of electronic device 400 at an early stage of manufacture. In the example shown in FIG. 11A, carrier 50″ can be provided. In some examples, first interconnect structure 450a, second interconnect structure 450b, and third interconnect structure 450c can be attached (or provided, coupled, or formed) on the upper side or inner side of carrier 50″. In the present example, the ends of interconnect structures 350a, 350b, and 350c that are attached to carrier 50″ can be referred to as distal ends and the opposite ends of interconnect structures 350a, 350b, and 350c can be referred to as proximate ends. In the present example, the proximate ends of interconnect structures 350a, 350b, and 350c are adjacent to active sides of first electronic component 420a and second electronic component 420b.

In some examples, first interconnect structure 450a and third interconnect structure 450c can be respectively located on carrier 50″ adjacent opposite sides of electronic components 420a and 420b, and second interconnect structure 450b can be located on carrier 50″ between adjacent sides of electronic components 420a and 420b. In some examples, first electronic component 420a and second electronic component 420b can be coupled (including attached) to the upper side or inner side of carrier 50″. In some examples, more than three interconnect structures 450 and more than two electronic components 420a and 420b can be provided. In some examples, carrier 50″ is provided and then interconnect structures 450 and electronic components 420a and 420b are then coupled to carrier 50″ in either order or simultaneously. First interconnect structure 450a, second interconnect structure 450b, and third interconnect structure 450c can comprise or be referred to as conductive pillars or pillar structures.

In some examples, after providing first interconnect structure 450a, second interconnect structure 450b, and third interconnect structure 450c, first electronic component 420a and second electronic component 420b can be provided and coupled to the upper side of carrier 50″. In some examples, first electronic component first side 421a of first electronic component 420a and second electronic component first side 421b of second electronic component 420b can each comprise or be referred to as an active side. In some examples, the active sides of first electronic component 420a and second electronic component 420b are placed distal to or face up with respect to the inner side of carrier 50″. In some examples, first electronic component second side 422a of first electronic component 420a and second electronic component second side 422b of second electronic component 420b can each comprise or be referred to as an inactive side. In some examples, the inactive sides of first electronic component 420a and second electronic component 420b can be attached to the inner side of carrier 50″ by first electronic component contact pad 424a and second electronic component contact pad 424b respectively. In some examples, first electronic component contact pad 424a and second electronic component contact pad 424b, can comprise or be referred to as a die-attach film (DAF) or a thermal interface material (TIM).

In some examples, first interconnect structure 450a, second interconnect structure 450b, and third interconnect structure 450c can be formed of a wire or by plating. First interconnect structure 450a, second interconnect structure 450b, and third interconnect structure 450c can be laterally spaced apart from first electronic component 420a and second electronic component 420b. In some examples, the heights of first interconnect structure 450a, second interconnect structure 450b, and third interconnect structure 450c can be greater than or equal to the thicknesses of first electronic component 420a and second electronic component 420b as referenced from the inner side of carrier 50″. In some examples, first interconnect structure 450a, second interconnect structure 450b, and third interconnect structure 450c can be provided at the center (that is, between first electronic component 420a and second electronic component 420b) and on both sides based on first electronic component 420a and second electronic component 420b.

Accordingly, a shielding structure can be individually provided for each of first electronic component 420a and second electronic component 420b. In some examples, EMI shielding can be provided for first electronic component 420a and second electronic component 420b. In some examples, carrier 50″ of electronic device 400 can be similar to carrier 10 of electronic device 100. In some examples, first interconnect structure 450a, second interconnect structure 450b, and third interconnect structure 450c of electronic device 400 can be similar to interconnect structures 150 of electronic device 100. In some examples, first electronic component 420a and second electronic component 420b of electronic device 400 can be similar to the electronic component 120 of the electronic device 100.

FIG. 11B shows a cross-sectional view of electronic device 400 at a later stage of manufacture. In the example shown in FIG. 11B, encapsulant 440 can be provided over carrier 50″. In some examples, encapsulant 440 can be provided to cover first electronic component 420a, second electronic component 420b, first interconnect structure 450a, second interconnect structure 450b, and third interconnect structure 450c.

FIG. 11C shows a cross-sectional view of electronic device 400 at a later stage of manufacture. In the example shown in FIG. 11C, the top portion of encapsulant 440 can be removed to expose the upper sides or proximate ends of first interconnect structure 450a, second interconnect structure 450b, and third interconnect structure 450c; and to expose upper sides of first connectors 423a and second connectors 423b. In some examples, using first connectors 423a on first electronic component first side 421a of first electronic component 420a and second connectors 423b on second electronic component first side 421b of second electronic component 420b as a stop layer can keep first electronic component 420a and second electronic component 420b undamaged during removal of an upper portion of encapsulant 440. In some examples, the top portion of encapsulant 440 can be removed by grinding, polishing, etching, or combinations thereof.

In some examples, when the top portion of encapsulant 440 is removed, the top portions of first interconnect structure 450a, second interconnect structure 450b, and third interconnect structure 450c can also be removed to define the proximate ends of these interconnect structures. In some examples, the upper side of encapsulant 440 can be coplanar with the upper sides or proximate ends of first interconnect structure 450a, second interconnect structure 450b, and third interconnect structure 450c, and the upper sides of first connectors 423a and second connectors 423b. The thickness of encapsulant 440 and the heights of first interconnect structure 450a, second interconnect structure 450b, and third interconnect structure 450c as referenced from the upper side or inner side of carrier 50″ can be similar.

In some examples, encapsulant 440 can be in contact with the inner side of carrier 50″, the sidewalls of first interconnect structure 450a, second interconnect structure 450b, and third interconnect structure 450c, and the sidewalls and the upper sides of first electronic component 420a and second electronic component 420b. In the present example, the sidewalls of first interconnect structure 450a, second interconnect structure 450b, and third interconnect structure 450c, and the sidewalls and the upper sides of first electronic component 420a and second electronic component 420b are embedded inside of encapsulant 440. In some examples, sidewalls of first connectors 423a and second connectors 423b are embedded inside encapsulant 440. In some examples, the upper side of first connectors 423a and second connectors 423b can be exposed from and substantially coplanar with the inner side (that is, the side where the top portion was removed) of encapsulant 440. In some examples, encapsulant 440 of electronic device 400 can be similar to encapsulant 140 of electronic device 100.

FIG. 11D shows a cross-sectional view of electronic device 400 at a later stage of manufacture. In the example shown in FIG. 11D, substrate 410 can be provided attached, coupled, or formed over the upper sides or proximate ends of first interconnect structure 450a, second interconnect structure 450b, and third interconnect structure 450c; over exposed portions of encapsulant 440; and over and adjacent to first electronic component first side 421a of first electronic component 420a and second electronic component first side 421b of second electronic component 420b. In some examples, substrate 410 comprises an RDL substrate that is formed or built-up layer by layer to provide individual layers of conductive structure 412 (including substrate inward terminals 412a and substrate outward terminals 412b) and individual layers of dielectric structure 411. In some examples, substrate inward terminals 412a can be provided connected to proximate ends of first interconnect structure 450a, second interconnect structure 450b, and third interconnect structure 350c and connected to first connectors 423a and second connectors 423b exposed from encapsulant 340.

In some examples, after substrate 310 is provided, external interconnects 470 can be provided coupled to substrate outward terminals 412b of substrate 410. In some examples, a plurality of external interconnects 470 can be provided and can be connected to substrate outward terminals 412b. In some examples, substrate 410 and external interconnects 470 of electronic device 400 can be similar to substrate 110 and external interconnects 170 of electronic device 100.

FIG. 11E shows a cross-sectional view of electronic device 400 at a later stage of manufacture. In the present example, electronic device 400 can be provided as a plurality of electronic devices 400 in wafer, panel, or substrate form. In the example shown in FIG. 11E, a process of flipping (or turning over) electronic device 400 can be performed. In some examples, carrier 50″ can be removed. In some examples, the distal ends of first interconnect structure 450a, second interconnect structure 450b, and third interconnect structure 450c and first electronic component contact pad 424a of first electronic component 420a and second electronic component contact pad 424b of second electronic component 420b can be exposed from encapsulant 440 after carrier 50″ is removed. In some examples, protection film 471 can be applied over external interconnects 470. Protection film 471 can suppress solder bridging and enhance mechanical stability of the subassembly for further processing. In some examples, protection film 471 can comprise, or be referred to as, a BGA film, Ajinomoto Build-up Film (ABF), a BT-based build-up dielectric film, or a photo-imageable PI/PBO dielectric film. In some examples, external interconnects 470 embedded within and covered by protection film 471. In some examples, protection film 471 directly contacts the outer side of substrate 410.

FIG. 11F shows a cross-sectional view of electronic device 400 at a later stage of manufacture. In the example shown in FIG. 11F, shield 460 can be provided over an exposed portion containing first interconnect structure 450a, second interconnect structure 450b, third interconnect structure 450c, first electronic component contact pad 424a, and second electronic component contact pad 424b. Shield 460 can connect first interconnect structure 450a, second interconnect structure 450b, and third interconnect structure 450c to one another, thereby shielding first electronic component 420a and second electronic component 420b. In some examples, first interconnect structure 450a, second interconnect structure 450b, third interconnect structure 450c, and shield 460 can reduce the effects of electromagnetic waves generated from first electronic component 420a and second electronic component 420b from being radiated. In some examples, first interconnect structure 450a, second interconnect structure 450b, third interconnect structure 450c, and shield 460 can reduce the effects of externally applied electromagnetic waves from entering first electronic component 420a and second electronic component 420b. In some examples, shield 460 of electronic device 400 can be similar to shield 160 of electronic device 100. Shield 460 can comprise or be referred to as a top shield and is provided without overlapping onto the lateral sides of encapsulant 440.

FIG. 11G is a cross-sectional view of electronic device 400 at a later stage of manufacture. In some examples, electronic device 400 can be singulated from the plurality of electronic device 400 provided as a wafer, panel, or substrate. In the present example, the panel of electronic devices can be singulated through shield 460, then through encapsulant 440, then through substrate 410, and then through protection film 471 to provide individual electronic devices 400. In some examples, the singulation method of electronic device 400 can be similar to the singulation method of electronic device 100. In some examples, protection film 471 can then be removed, and a finished or near-finished electronic device 400 can be provided.

In the example shown in FIG. 11G, electronic device 400 can individually shield first electronic component 420a and second electronic component 420b through first interconnect structure 450a, second interconnect structure 450b, and third interconnect structure 450c. In some examples, electronic device 400 can individually shield first electronic component 420a and second electronic component 420b through shield 460. In some examples, shield 460 can interconnect first interconnect structure 450a, second interconnect structure 450b, and third interconnect structure 450c at the upper end of first interconnect structure 450a, second interconnect structure 450b, and third interconnect structure 450c. In the present example, shield 460 is coupled including contacting first electronic component contact pad 424a of first electronic component 420a and second electronic component contact pad 424b of second electronic component 420b to allow heat to transfer without passing through molding compound, reducing package thermal resistance and enhancing EMI shielding performance.

In accordance with the present description, shield 460 can be provided without additional plating and reconstruction processes, which eliminates several process steps compared to prior approaches to forming shield structures.

In some examples, the implications of package edge exclusion requirements of previous package structures, such as keep-out zones, of electronic device 400 (or package) can be minimized by applying a wafer-level shield rather than a can-level shield. In accordance with the present description, electronic device 400 does not require a reconstruction process or a sputtering process to provide side shielding, which instead is provided by interconnect structures 450. Among other things, this reduces manufacturing steps, complexity, and cost.

In accordance with the present description, first interconnect structure 450a, second interconnect structure 450b, and third interconnect structure 450c can be arranged in any of a variety of configurations including those illustrated in FIG. 6

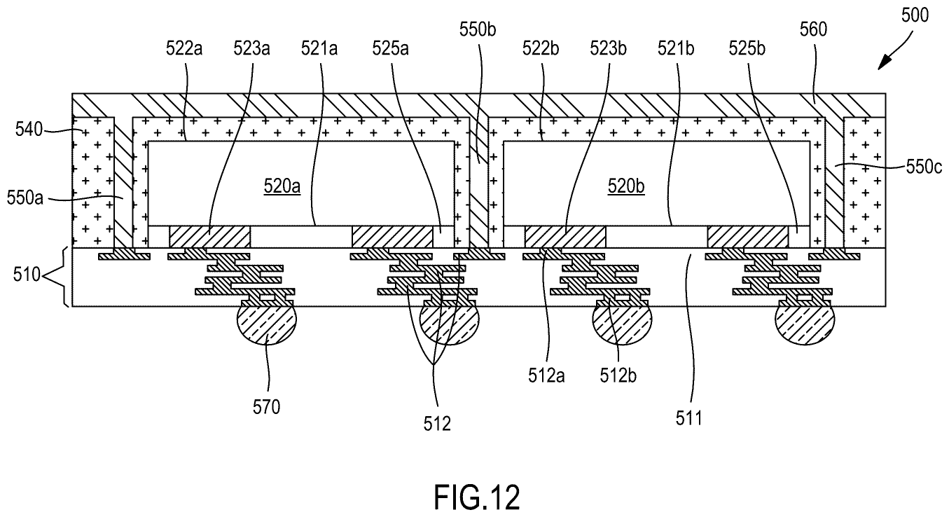

FIG. 12 shows a cross-sectional view of an example electronic device 500. In the present example, electronic device 500 can be similar to the structure and manufacturing method of final electronic device 100 shown in FIG. 1. However, it is understood that other methods or steps, such as addition or removal of components, can be performed to manufacture electronic device 500. Electronic device 500 can be referred to as a semiconductor package, an electronic device, an electronic package, a device, or a package. In some examples, electronic device 500 can comprise substrate 510, first electronic component 520a, second electronic component 520b, encapsulant 540, first interconnect structure 550a, second interconnect structure 550b, third interconnect structure 550c, shield 560, and external interconnects 570.

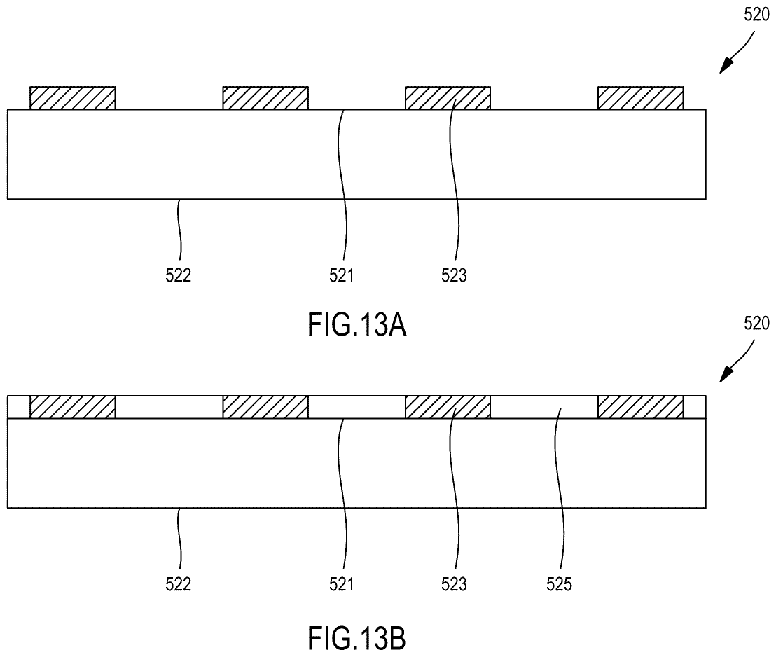

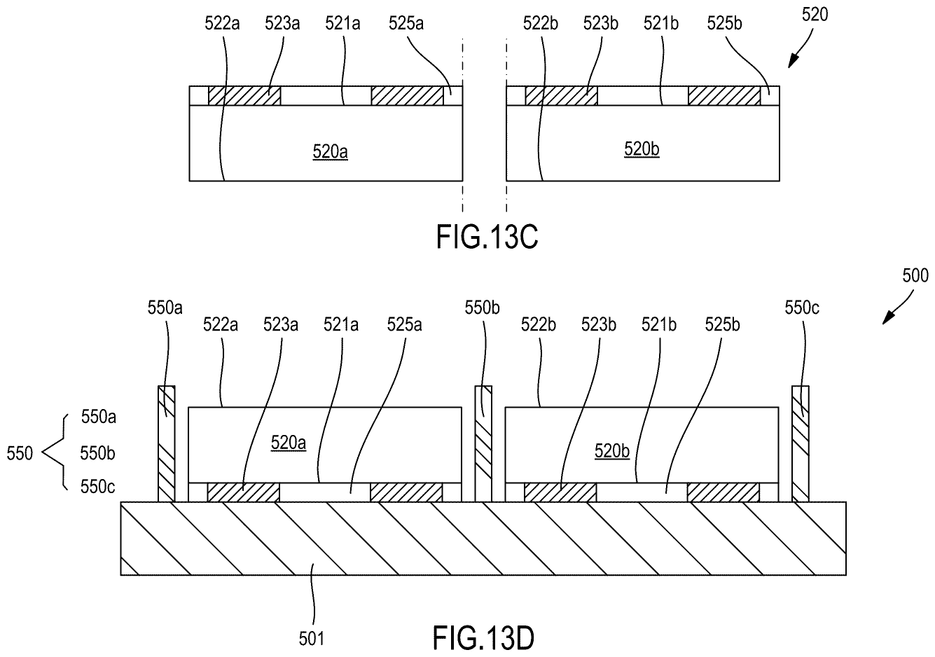

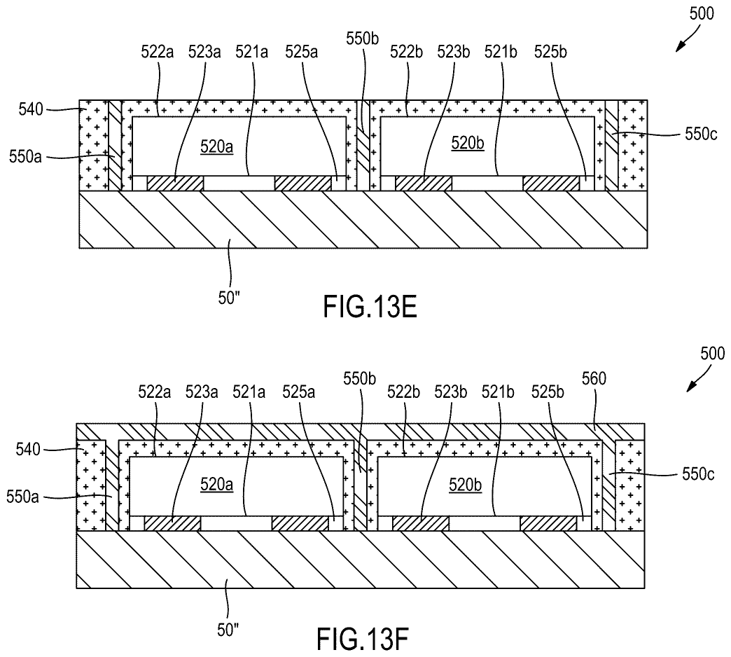

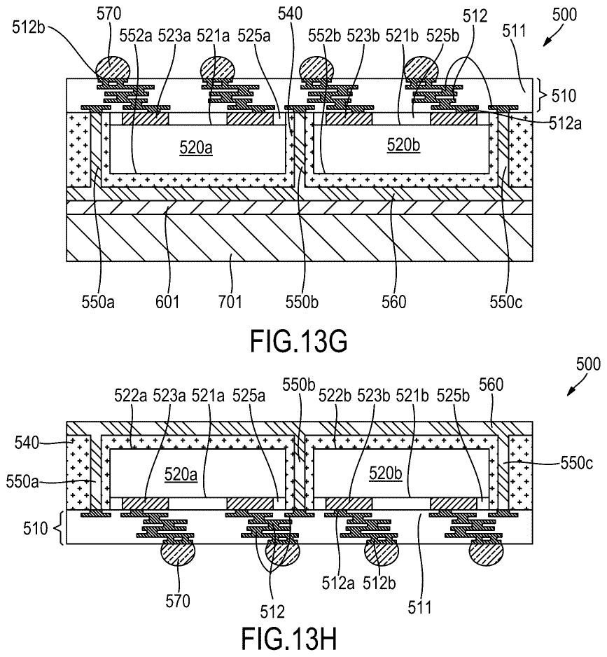

In some examples, substrate 510 can comprise dielectric structure 511 and conductive structure 512. Conductive structure 512 can comprise substrate inward terminals 512a and substrate outward terminals 512b. First electronic component 520a can comprise first electronic component first side 521a, first electronic component second side 522a, first connectors 523a, and first connector encapsulant 525a. In some examples, second electronic component 520b can comprise second electronic component first side 521b, second electronic component second side 522b, second connectors 523b, and second connector encapsulant 525b. Any elements described in FIGS. 12 and 13A-13H can be similar to any corresponding elements described in FIGS. 1-11.

FIGS. 13A, 13B, 13C, 13D, 13E, 13F, 13G, and 13H are cross-sectional views showing various electronic device manufacturing methods, according to various aspects of the present description, which can be used to provide electronic device 500. This method can comprise or be referred to as a die or component first face-down process. This includes a plurality of structures configured as a wafer, panel, or substrate to be singulated into a plurality of electronic devices. In the present example, the electronic components and interconnect structures are provided in an early stage of fabrication, the encapsulant (encapsulant 540), and the shield are then provided. The substrate and external interconnects are provided at a later stage of fabrication. In the present example, the shield (shield 560) is provided before the substrate (substrate 510). This can also be referred to as a shield first and substrate second method.

FIG. 13A shows a cross-sectional view of electronic device 500 at an early stage of manufacture. In the example shown in FIG. 13A, electronic component 520 can be provided. In some examples, electronic component 520 can be referred to as an electronic device wafer (for example, semiconductor wafer with a plurality of electronic devices configured to be subsequently separated into individual devices), a device wafer, a device panel, or a device substrate. In some examples, electronic component 520 can comprise first electronic component side 521 and second electronic component side 522. In some examples, first electronic component side 521 can comprise or be referred to as an active side or upper side. Electronic component 520 is provided with connectors 523 over first electronic component side 521 or the active side of electronic component 520. In some examples, connectors 523 can comprise or be referred to as conductive pads or studs. In some examples, connectors 523 can comprise copper and can be formed using CVD, sputtering, evaporation, printing, depositing, or plating processes and photolithographic and etching processes.

FIG. 13B shows a cross-sectional view of electronic device 500 at a later stage of manufacture. In the example shown in FIG. 13B, connectors 523 can be covered by component encapsulant 525. Connector encapsulant 525 can be provided over first electronic component side 521 of electronic component 520. Connector encapsulant 525 can encapsulate or fill spaces between and around connectors 523. In some examples, connector encapsulant 525 can be provided as a molded structure to fully cover connectors 523 and then a portion of the molded structure can be removed to expose connectors 523 from the upper side of the molded structure. In some examples, grinding, polishing, etching, or combinations thereof can be used to remove a portion of the molded structure. In some examples, the top side of connectors 523 can be exposed from connector encapsulant 525.

FIG. 13C shows a cross-sectional view of electronic device 500 at an early stage of manufacture. In the example shown in FIG. 13C, a singulation process can be used to separate electronic component 520 into individual electronic devices. In some examples, the singulation can extend through connector encapsulant 525. In some examples sawing, laser separation, plasma etching, or combinations thereof can be used for the singulation process. In some examples, electronic component 520 can be attached to a singulation film, such as a tape for the singulation process. In some examples, electronic component 520 can be separated to provide first electronic component 520a and second electronic component 520b. In the present example, first electronic component 520a can comprise first electronic component first side 521a, first electronic component second side 522a, first connectors 523a, and first connector encapsulant 525a. Second electronic component 520b can comprise second electronic component first side 521b, second electronic component second side 522b, second connectors 523b, and second connector encapsulant 525b.

FIG. 13D shows a cross-sectional view of electronic device 500 at a later stage of manufacture. In the example shown in FIG. 13D, carrier 501 can be provided. In some examples, first interconnect structure 550a, second interconnect structure 550b, and third interconnect structure 550c can be attached (or provided, coupled, or formed) on the upper side or inner side of carrier 501. In the present example, the ends of interconnect structures 550a, 550b, and 550c that are attached to carrier 501 can be referred to as proximate ends and the opposite ends of interconnect structures 550a, 550b, and 350c can be referred to as distal ends. In the present example, first electronic component first side 521a and second electronic component first side 521b are active sides, which face the inner sides of carrier 501. In the present example, the proximate ends are adjacent to active sides of first electronic component 520a and second electronic component 520b.

In some examples, first interconnect structure 550a and third interconnect structure 550c can be respectively located on carrier 501 adjacent opposite sides of electronic components 520a and 520b. In some examples, second interconnect structure 550b can be located on carrier 501 between adjacent sides of electronic components 520a and 520b. In some examples, first electronic component 520a and second electronic component 520b can be coupled (including attached) to the upper side or inner side of carrier 501. In some examples, more than three interconnect structures 550 and more than two electronic components 520 can be provided. In some examples, carrier 501 is provided and then interconnect structures 550 and electronic components 520 are then coupled to carrier 501 in either order or simultaneously. First interconnect structure 550a, second interconnect structure 550b, and third interconnect structure 550c can comprise or be referred to as conductive pillars or pillar structures.

In some examples, after providing first interconnect structure 550a, second interconnect structure 550b, and third interconnect structure 550c, first electronic component 520a and second electronic component 520b can be provided and coupled to the inner side of carrier 501. In some examples, first electronic component first side 521a of first electronic component 520a and second electronic component first side 521b of second electronic component 520b can each comprise or be referred to as an active side, and the active sides of first electronic component 520a and second electronic component 520b are placed adjacent to and facing the inner side of carrier 501. In some examples, first electronic component 520a and second electronic component 520b are placed directly onto the temporary adhesive layer portion of carrier 501 without any intervening conductive pattern or substrate. In some examples, the proximate ends of first interconnect structure 550a, second interconnect structure 550b, and third interconnect structure 550c, first electronic component 520a and second electronic component 520b can be provided first connectors 523a, first connector encapsulant 525a second connectors 523b, and second connector encapsulant 525b contact the inner side of carrier 501.

In some examples, first interconnect structure 550a, second interconnect structure 550b, and third interconnect structure 550c can be formed of a wire or by plating. First interconnect structure 550a, second interconnect structure 550b, and third interconnect structure 550c can be laterally spaced apart from first electronic component 520a and second electronic component 520b. In some examples, the heights of first interconnect structure 550a, second interconnect structure 550b, and third interconnect structure 550c can be greater than or equal to the thicknesses of first electronic component 520a and second electronic component 520b as referenced from the inner side of carrier 501. In some examples, first interconnect structure 550a, second interconnect structure 550b, and third interconnect structure 550c can be located at the center and on both sides based on first electronic component 520a and second electronic component 520b. For example, second interconnect structure 550b can be provided between first electronic component 520a and second electronic component 520b, and first interconnect structure 550a and third interconnect structure 550c can be provided on the side portions of first electronic component 520a and second electronic component 520b, respectively.

Accordingly, a shielding structure can be individually provided in each of first electronic component 520a and second electronic component 520b. In some examples, first interconnect structure 550a, second interconnect structure 550b, and third interconnect structure 550c can be provided along the perimeter of first electronic component 520a and second electronic component 520b. In some examples, EMI shielding can be provided for first electronic component 520a and second electronic component 520b. In some examples, carrier 501 of electronic device 500 can be similar to carrier 10 of electronic device 100. In some examples, first interconnect structure 550a, second interconnect structure 550b, and third interconnect structure 550c of electronic device 500 can be similar to interconnect structures 150 of electronic device 100. In some examples, first electronic component 520a and second electronic component 520b of electronic device 500 can be similar to the electronic component 120 of the electronic device 100.

FIG. 13E shows a cross-sectional view of electronic device 500 at a later stage of manufacture. In the example shown in FIG. 13E, encapsulant 540 can be provided over the inner side of carrier 501. In some examples, encapsulant 540 can be provided to cover first electronic component 520a, second electronic component 520b, first interconnect structure 550a, second interconnect structure 550b, and third interconnect structure 550c. The top portion of encapsulant 540 can be removed to expose the upper sides or distal ends of first interconnect structure 550a, second interconnect structure 550b, and third interconnect structure 550c. In some examples, the top portion of encapsulant 540 can be removed by grinding, polishing, etching or combinations thereof.

In some examples, when the top portion of encapsulant 540 is removed, the top portions of first interconnect structure 550a, second interconnect structure 550b, and third interconnect structure 550c can also be removed to define the distal ends these interconnect structures. In some examples, the upper side of encapsulant 540 can be coplanar with the distal ends of first interconnect structure 550a, second interconnect structure 550b, and third interconnect structure 550c. In other examples, the distal ends of first interconnect structure 550a, second interconnect structure 550b, and third interconnect structure 550c can be recessed inward with respect to the upper side of encapsulant 540. In some examples, the thickness of encapsulant 540 and the heights of first interconnect structure 550a, second interconnect structure 550b, and third interconnect structure 550c can be similar as referenced from the upper side or inner side of carrier 501.

In some examples, encapsulant 540 can be in contact with the inner side of carrier 501, the sidewalls of first interconnect structure 550a, second interconnect structure 550b, and third interconnect structure 550c, and the sidewalls and the upper sides of first electronic component 520a and second electronic component 520b. In the present example, the sidewalls of first interconnect structure 550a, second interconnect structure 550b, and third interconnect structure 550c, and the sidewalls and the upper sides of first electronic component 520a and second electronic component 520b are embedded inside of encapsulant 540. In some examples, encapsulant 540 of electronic device 500 can be similar to encapsulant 140 of electronic device 100.

FIG. 13F shows a cross-sectional view of electronic device 500 at a later stage of manufacture. In the example shown in FIG. 13F, shield 560 can be provided on the upper sides or distal ends of first interconnect structure 550a, second interconnect structure 550b, and third interconnect structure 550c. In some examples, shield 560 can be provided over the top side of encapsulant 540. Shield 560 can couple first interconnect structure 550a, second interconnect structure 550b, and third interconnect structure 550c to one another, thereby shielding first electronic component 520a and second electronic component 520b. In some examples, first interconnect structure 550a, second interconnect structure 550b, third interconnect structure 550c, and shield 560 can reduce the effects of electromagnetic waves generated from first electronic component 520a and second electronic component 520b from being radiated. In some examples, first interconnect structure 550a, second interconnect structure 550b, third interconnect structure 550c, and shield 560 can reduce the effects of externally applied electromagnetic waves from entering first electronic component 520a and second electronic component 520b. In some examples, shield 560 of electronic device 500 can be similar to shield 160 of electronic device 100. Shield 560 can comprise or be referred to a top shield and is provided without overlapping onto the lateral sides of encapsulant 540.

FIG. 13G shows a cross-sectional view of electronic device 500 at a later stage of manufacture. In the example shown in FIG. 13G, carrier 501 has been removed. In some examples, the temporary bonding layer can also be removed. In an example implementation, film substrate 601 and carrier 701 can be coupled to or bonded to shield 560 (for example, on the opposite side of carrier 501), and carrier 501 and the temporary bonding layer can then be removed as described previously with carrier 10. In the present example, after carrier 501 is removed, the proximate ends of first interconnect structure 550a, second interconnect structure 550b, third interconnect structure 550c, the outer sides of first connectors 323a, the outer sides of second connectors 323b, first connector encapsulant 525a, and second connector encapsulant 525b are exposed from encapsulant 340. In the present example, the proximate ends of first interconnect structure 550a, second interconnect structure 550b, third interconnect structure 550c, the outer sides of first connectors 523a, the outer sides of second connectors 523b, first connector encapsulant 525a, and second connector encapsulant 525b are substantially coplanar with the inner side of encapsulant 540. In the present example, shield 560 is oriented to be adjacent to the inner side of carrier 701 and the active sides of first electronic component 520a and second electronic component 520b are oriented away from the inner side of carrier 701. In some examples, film substrate 601 and carrier 701 of electronic device 500 can be similar to film substrate 20 and carrier 30 of electronic device 100.

In some examples, substrate 510 can be provided at the location where carrier 501 has been removed. In the present example, substrate 510 can be provided attached, coupled, or formed over the lower sides or proximate ends of first interconnect structure 550a, second interconnect structure 550b, and third interconnect structure 550c; over the lower side of encapsulant 540; over the active sides of first electronic component 520a and second electronic component 520b; and over first connector encapsulant 525a and second connector encapsulant 525b. In some examples, substrate 310 comprises an RDL substrate that is formed or built-up layer by layer to provide individual layers of conductive structure 512 (including substrate inward terminals 512a and substrate outward terminals 512b) and individual layers of dielectric structure 511. In some examples, substrate inward terminals 512a can be provided connected to proximate ends of first interconnect structure 550a, second interconnect structure 550b, and third interconnect structure 550c, and connected to first connectors 523a and second connectors 523b exposed from encapsulant 540.

In some examples, after substrate 510 is provided, external interconnects 570 can be provided coupled to substrate outward terminals 512b of substrate 510. In some examples, a plurality of external interconnects 570 can be provided and can be connected to substrate outward terminals 512b. In some examples, substrate 510 and external interconnects 570 of electronic device 500 can be similar to substrate 110 and external interconnects 170 of electronic device 100.

FIG. 13H is a cross-sectional view of electronic device 500 at a later stage of manufacture. In some examples, carrier 701 can then be separated while leaving film substrate 601 in place. In some examples, film substrate 601 can be used as a singulation substrate or an additional singulation substrate can be coupled to film substrate 601, such as singulation substrate 155 described previously. In the present example, electronic device 500 can be provided as a plurality of electronic devices 500 in wafer, panel, or substrate form. In the present example, the panel of electronic devices 500 can be singulated through substrate 510, then through encapsulant 540, and then through shield 560 to provide individual electronic devices 500. In some examples, film substrate 601 can be removed to provide a finished or near finished electronic device 300. In some examples, the singulation method of electronic device 500 can be similar to the singulation method of electronic device 100 or electronic device 200.

In the example shown in FIG. 13H, electronic device 500 can individually shield first electronic component 520a and second electronic component 520b through first interconnect structure 550a, second interconnect structure 550b, and third interconnect structure 550c. In some examples, electronic device 500 can individually shield first electronic component 520a and second electronic component 520b through shield 560. In some examples, shield 560 can interconnect first interconnect structure 550a, second interconnect structure 550b, and third interconnect structure 550c at the upper ends or distal ends of first interconnect structure 550a, second interconnect structure 550b, and third interconnect structure 550c. In accordance with the present description, shield 560 can be provided without additional plating and reconstruction processes, which eliminates several process steps compared to prior approaches to forming shield structures.

In some examples, the implications of package edge exclusion requirements of previous package structures, such as keep-out zones, of electronic device 500 (or package) can be minimized by applying a wafer-level shield rather than a can-level shield. In accordance with the present description, electronic device 500 does not require a reconstruction process or a sputtering process to provide side shielding, which instead is provided by interconnect structures 550. Among other things, this reduces manufacturing steps, complexity, and cost.

In accordance with the present description, first interconnect structure 550a, second interconnect structure 550b, and third interconnect structure 550c can be arranged in any of a variety of configurations including those illustrated in FIG. 6.

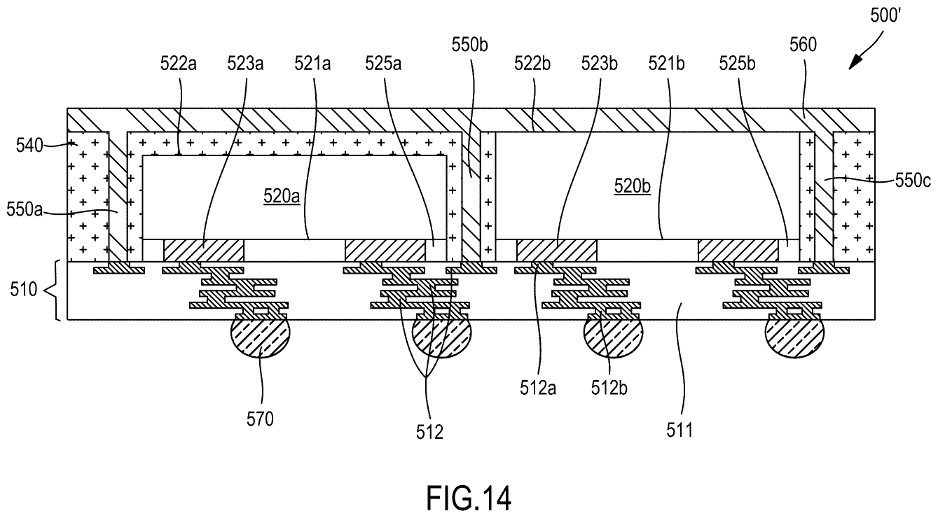

FIG. 14 shows a cross-sectional view of an example electronic device 500′, which can have similarity to the structure and manufacturing method of electronic device 500 shown in FIG. 12. However, it is understood that other methods or steps, such as addition or removal of components, can be performed to manufacture electronic device 500′. In the example shown in FIG. 14, the heights of first electronic component 520a and second electronic component 520b can be different. In some examples, second electronic component 520b can be thicker than first electronic component 520a and can be coupled to shield 560. In some examples, second electronic component second side 522b of second electronic component 520b can be in contact with shield 560.

In some examples, second electronic component 520b can be disposed within encapsulant 540, and then second electronic component second side 522b of second electronic component 520b can be exposed by removing an upper portion of encapsulant 540. Shield 560 can be provided to contact electronic component second side 522b of second electronic component 520b. In some examples, this can be done while exposing the distal ends of interconnect structures 550a, 550b, and 550c. Shield 560 can be then provided to contact electronic component second side 522b of second electronic component 520b. In this configuration, coupling between shield 560 and second electronic component 520b can allow heat to transfer without passing through encapsulant 540, thereby reducing package thermal resistance while also enhancing EMI shielding performance. In some examples, a thermal interface material (TIM) can be provided between second electronic component second side 522b and shield 560 to improve adhesion between shield 560 and second electronic component 520b or to further enhance heat transfer.

In some examples, first electronic component 520a and shield 560 can be separated without contacting each other. The portion of encapsulant 540 interposed between shield 560 and first electronic component 520a can absorb thermal and mechanical stress. In the present example, by using planar grinding to remove a portion of encapsulant 540 followed by deposition of only a top conductive film to provide shield 560 can simplify processing and enable a smaller package profile and footprint.

In summary, structures and associated methods that relate to electronic devices including, for example, semiconductor devices, configured with electromagnetic interference (EMI) shield structures have been described. In some examples, wafer-level assembly processes are used to simplify connectivity to shield structures and to avoid the implications of package edge exclusion requirements of previous package structures, such as keep-out zones. In some examples, conductive interconnects, electronic components, an encapsulant, and a top shield are provided using a carrier prior to providing a substrate coupled to the electronic components and the conductive interconnects. External interconnects can be provided after providing the substrate. In other examples, the substrate is provided on a carrier, the conductive interconnects, electronic components, encapsulant, and top shield are then provided. After removing the carrier, external interconnects are then provided coupled to the substrate. Among other things, the structures and methods provide an electronic package with improved performance and reliability by reducing susceptibility to EMI and by improving thermal performance.

The present description includes reference to certain examples, however, it will be understood by those skilled in the art that various changes can be made and equivalents can be substituted without departing from the scope of the disclosure. In addition, modifications can be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, comprising:
providing a first carrier comprising an inner side;
coupling interconnect structures to the inner side of the first carrier;
providing a first electronic component comprising a first electronic component first side and a first electronic component second side;
coupling the first electronic component to the inner side of the first carrier;
providing an encapsulant covering the interconnect structures and the first electronic component;
exposing upper ends of the interconnect structures from an outer side of the encapsulant;
in either order:
providing a package substrate coupled to the first electronic component and the interconnect structures; and
providing a shield over the encapsulant and coupled to the interconnect structures; and
singulating the package substrate, the encapsulant, and the shield to provide the electronic device.

2. The method of claim 1, wherein:
providing the first electronic component comprises providing the first electronic component first side comprising an active side;
coupling the first electronic component comprises coupling the first electronic component first side to the inner side of the first carrier; and
providing the shield occurs before providing the package substrate.

3. The method of claim 2, further comprising:
after providing the shield, attaching a second carrier to the shield;
removing the first carrier to expose lower ends of the interconnect structures and the first electronic component first side; and
after removing the first carrier, providing the package substrate coupled to the lower ends of the interconnect structures and the first electronic component first side.

4. The method of claim 1, wherein:
providing the first electronic component comprises providing the first electronic component first side comprising an active side and the first electronic component second side comprising an inactive side;
coupling the first electronic component comprises coupling the first electronic component second side to the inner side of the first carrier;
the method further comprises exposing the first electronic component first side from the outer side of the encapsulant; and
providing the package substrate occurs before providing the shield.

5. The method of claim 4, further comprising:
providing external interconnects coupled to the package substrate;
providing a protective film over the external interconnects;
removing the first carrier; and
providing the shield after removing the first carrier.

6. The method of claim 1, wherein:
coupling the interconnect structures comprises bonding wires to the inner side of the first carrier.

7. The method of claim 1, wherein:
providing the package substrate comprises providing a redistribution layer (RDL) substrate.

8. A method of manufacturing an electronic device, comprising:
providing a first carrier comprising an inner side;
coupling interconnect structures and a first electronic component to the first carrier, wherein an active side of the first electronic component and proximate ends of the interconnect structures are adjacent to the inner side of the first carrier;
providing encapsulant covering the interconnect structures and the first electronic component;
removing a top portion of the encapsulant to expose distal ends of the interconnect structures;
providing a shield over a top side of the encapsulant, wherein the shield is coupled to the interconnect structures;
removing the first carrier;
coupling a second carrier to the shield;
providing a substrate coupled to the proximate ends of the interconnect structures and the active side of the first electronic component; and
singulating the substrate, the encapsulant, and the shield to provide the electronic device.

9. The method of claim 8, further comprising:
coupling external interconnects to an outer side of the substrate.

10. The method of claim 8, wherein:
providing the substrate comprises providing a redistribution layer substrate (RDL substrate).

11. The method of claim 8, wherein:
coupling the second carrier comprises:
attaching a film substrate to the shield; and
attaching a carrier substrate to the film substrate.

12. The method of claim 11, further comprising:
removing the carrier substrate but leaving the film substrate in place before the singulating.

13. The method of claim 8, further comprising:
providing the first electronic component as part of a device wafer;
providing conductive pads on the active side of the first electronic component;
providing a molded structure between the conductive pads, wherein the conductive pads are exposed from an upper side of the molded structure; and
singulating the device wafer to provide the first electronic component.

14. The method of claim 8, further comprising:
coupling a second electronic component to the first carrier and laterally spaced apart from the first electronic component, wherein the second electronic component comprises a second electronic component first side and a second electronic component second side.

15. The method of claim 14, wherein providing the shield comprises coupling the shield to the second electronic component second side.

16. The method of claim 14, wherein:
coupling the interconnect structures comprises:
coupling a first interconnect structure adjacent to a first lateral side of the first electronic component proximate to a first edge of the first carrier;
coupling a second interconnect structure between a second lateral side of the first electronic component and a first lateral side of the second electronic component; and
coupling a third interconnect structure adjacent to a second lateral side of the second electronic component proximate to a second edge of the first carrier.

17. The method of claim 8, wherein:
coupling the interconnect structures comprises coupling conductive pillars.

18. The method of claim 8, wherein:
coupling the first electronic component comprises:
providing the first electronic component comprising a first electronic component first side, a first electronic component second side; and first connectors located at the first electronic component first side; and
attaching the first connectors to the inner side of the first carrier; and
providing the encapsulant comprises providing the encapsulant comprising an encapsulant inner side coplanar with upper sides of the first connectors.

19. An electronic device, comprising:
a redistribution layer substrate (RDL substrate) comprising an inner side and an outer side;
electronic components comprising component connectors coupled to the inner side of the RDL substrate;
interconnect structures coupled to the inner side of the RDL substrate and adjacent to the electronic components;
an encapsulant covering the electronic components and the interconnect structures, wherein distal ends of the interconnect structures are exposed from an upper side of the encapsulant;
a top shield on the upper side of the encapsulant and coupled to the interconnect structures, wherein the encapsulant comprises lateral sides, and wherein the lateral sides are devoid of the top shield; and
external interconnects coupled to the outer side of the RDL substrate, wherein the top shield and the interconnect structures provide a shielding structure for the electronic device.

20. The electronic device of claim 19, wherein:
the component connectors and proximate ends of the interconnect structures are coplanar with an inner side of the encapsulant; and
one of the electronic components comprises an electronic component side coupled to the top shield.
